(19) United States
(12) Patent Application Publication
(10) Pub. No.: US 2026/0231760 A1
(43) Pub. Date: Aug. 6, 2026

(54) SEMICONDUCTOR PACKAGES AND METHODS OF FORMING THE SAME

(71) Applicant: Taiwan Semiconductor Manufacturing Company Limited, Hsinchu (TW)

(72) Inventor: Wei WU, Hsinchu (TW)

(21) Appl. No.: 19/043,703

(22) Filed: Feb. 3, 2025

(51) Int. Cl. H01L 23/367; H01L 21/50; H01L 23/00; H01L 23/40; H01L 23/538; H01L 25/00; H01L 25/07

(52) U.S. Cl. CPC H10W 40/22; H10W 40/611; H10W 70/611; H10W 90/00; H10W 90/401; H10W 95/00; H10W 90/734; H10W 90/736

(57) ABSTRACT

A packaging structure may be formed by: attaching a lid structure to a bonded assembly including at least one semiconductor die and a packaging substrate, and wherein the lid structure includes at least one threaded hole vertically extending from a top surface of the lid structure toward the bonded assembly; providing a heat sink including at least one through-hole; and passing at least one threaded fastener through a respective one of the at least one through-hole and engaging each of the at least one threaded fastener into a respective one of the at least one threaded hole, whereby the heat sink is affixed to the lid structure.

### BACKGROUND

Semiconductor packages generate heat during operation, which may degrade performance and reliability in instances in which the generated heat is not efficiently managed. Heat sinks may be used to effectively dissipate the heat from the semiconductor packages, to maintain the semiconductor packages at a controlled operating temperature, to maintain an optimal performance level, and to prolong the lifetime of the semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary intermediate structure after formation of a through interposer via (TIV) structures over a first carrier wafer according to an embodiment of the present disclosure.

FIG. 2A is a vertical cross-sectional view of the exemplary intermediate structure after attaching local silicon interconnect (LSI) bridges to the first carrier wafer according to an embodiment of the present disclosure. FIG. 2B is a top-down view of the exemplary intermediate structure of FIG. 2A. FIG. 2C is a vertical cross-sectional view of an LSI bridge in the exemplary intermediate structure of FIGS. 2A and 2B.

FIG. 3 is a vertical cross-sectional view of the exemplary intermediate structure after formation of an interposer-level molding compound material layer according to an embodiment of the present disclosure.

FIG. 4 is a vertical cross-sectional view of the exemplary intermediate structure after formation of an interposer-level molding compound matrix according to an embodiment of the present disclosure.

FIG. 5 is a vertical cross-sectional view of the exemplary intermediate structure after formation of a first redistribution structure according to an embodiment of the present disclosure.

FIG. 6 is a vertical cross-sectional view of the exemplary intermediate structure after attaching semiconductor dies to the first redistribution structure according to an embodiment of the present disclosure.

FIG. 7 is a vertical cross-sectional view of the exemplary intermediate structure after formation of die-side underfill material portions according to an embodiment of the present disclosure.

FIG. 8 is a vertical cross-sectional view of the exemplary intermediate structure after formation of a die-level molding compound matrix according to an embodiment of the present disclosure.

FIG. 9 is a vertical cross-sectional view of the exemplary intermediate structure after attaching a second carrier wafer to a reconstituted wafer and detaching the first carrier wafer according to an embodiment of the present disclosure.

FIG. 10 is a vertical cross-sectional view of the exemplary intermediate structure after formation of a second redistribution structure according to an embodiment of the present disclosure.

FIG. 11 is a vertical cross-sectional view of a composite package according to an embodiment of the present disclosure.

FIG. 12 is a vertical cross-sectional view of a bonded assembly comprising the composite package and a packaging substrate according to an embodiment of the present disclosure.

FIG. 13A is a vertical cross-sectional view of a first exemplary packaging structure formed by attaching a lid structure to the bonded assembly according to an embodiment of the present disclosure. FIG. 13B is a top-down view of the packaging structure of FIG. 13A. The vertical plane A-A′ in FIG. 13B is the cut plane of the vertical cross-sectional view of FIG. 13A.

FIG. 14A is a vertical cross-sectional view of the first exemplary packaging structure after attaching a heat sink to the lid structure according to an embodiment of the present disclosure. FIG. 14B is a top-down view of the first exemplary packaging structure of FIG. 14A. The vertical plane A-A′ in FIG. 14B is the cut plane of the vertical cross-sectional view of FIG. 14A. FIG. 14C is a horizontal cross-sectional view of the packaging structure along the horizontal plane C-C′ of FIG. 14A. FIG. 14D is a vertical cross-sectional view of the first exemplary packaging structure along the vertical plane D-D′ in FIGS. 14B and 14C.

FIG. 15A is a vertical cross-sectional view of the first exemplary packaging structure after affixing threaded fasteners according to an embodiment of the present disclosure. FIG. 15B is a top-down view of the packaging structure of FIG. 15A. The vertical plane A-A′ in FIG. 15B is the cut plane of the vertical cross-sectional view of FIG. 15A. FIG. 15C is a perspective view of a first alternative configuration of the first exemplary structure. FIG. 15D is a perspective view of a second alternative configuration of the first exemplary structure.

FIG. 16 is a vertical cross-sectional view of the first exemplary packaging structure after attaching a printed circuit board according to an embodiment of the present disclosure.

FIG. 17A is a vertical cross-sectional view of a second exemplary packaging structure formed by attaching a lid structure to the bonded assembly of FIG. 12 according to an embodiment of the present disclosure. FIG. 17B is a top-down view of the packaging structure of FIG. 17A. The vertical plane A-A′ is the cut plane of the vertical cross-sectional view of FIG. 17A.

FIG. 18A is a vertical cross-sectional view of the second exemplary packaging structure after attaching a heat sink to the lid structure according to an embodiment of the present disclosure. FIG. 18B is a top-down view of the second exemplary packaging structure of FIG. 18A. The vertical plane A-A′ in FIG. 18B is the cut plane of the vertical cross-sectional view of FIG. 18A. FIG. 18C is a horizontal cross-sectional view of the packaging structure along the horizontal plane C-C′ of FIG. 18A. FIG. 18D is a vertical cross-sectional view of the second exemplary packaging structure along the vertical plane D-D′ in FIGS. 18B and 18C. FIG. 18E is a horizontal cross-sectional view of the second exemplary packaging structure along the horizontal plane E-E′ in FIGS. 18A and 18C. The vertical plane A-A′ in FIG. 18E is the cut plane of the vertical cross-sectional view of FIG. 18A. The vertical plane D-D′ in FIG. 18E is the cut plane of the vertical cross-sectional view of FIG. 18D.

FIG. 19 is a vertical cross-sectional view of the second exemplary packaging structure after affixing threaded fasteners according to an embodiment of the present disclosure.

FIG. 20 is a vertical cross-sectional view of the second exemplary packaging structure after attaching a printed circuit board according to an embodiment of the present disclosure.

FIG. 21A is a vertical cross-sectional view of a third exemplary packaging structure formed by attaching the second exemplary packaging structure of FIGS. 17A and 17B to a printed circuit board according to an embodiment of the present disclosure. FIG. 21B is a top-down view of the packaging structure of FIG. 21A. The vertical plane A-A′ is the cut plane of the vertical cross-sectional view of FIG. 21A.

FIG. 22A is a vertical cross-sectional view of the third exemplary packaging structure after attaching a heat sink to the lid structure according to an embodiment of the present disclosure. FIG. 22B is a top-down view of the third exemplary packaging structure of FIG. 22A. The vertical plane A-A′ in FIG. 22B is the cut plane of the vertical cross-sectional view of FIG. 22A. FIG. 22C is a horizontal cross-sectional view of the packaging structure along the horizontal plane C-C′ of FIG. 22A.

FIG. 23A is a vertical cross-sectional view of the third exemplary packaging structure after affixing additional threaded fasteners through the printed circuit board according to an embodiment of the present disclosure. FIG. 23B is a top-down view of the third exemplary packaging structure of FIG. 23A. The vertical plane A-A′ in FIG. 23B is the cut plane of the vertical cross-sectional view of FIG. 23A. FIG. 23C is a horizontal cross-sectional view of the packaging structure along the horizontal plane C-C′ of FIG. 23A.

FIG. 24 is a vertical cross-sectional view of an alternative configuration of the third exemplary packaging structure after affixing additional threaded fasteners through the printed circuit board to the heat sink according to an embodiment of the present disclosure.

FIG. 25 is a vertical cross-sectional view of a fourth exemplary packaging structure formed by attaching a lid structure to a bonded assembly according to an embodiment of the present disclosure.

FIG. 26 is a vertical cross-sectional view of the fourth exemplary packaging structure after attaching the bonded assembly to a printed circuit board and after attaching a heat sink according to an embodiment of the present disclosure.

FIG. 27A is a vertical cross-sectional view of the fourth exemplary packaging structure after attaching side heat sinks according to an embodiment of the present disclosure. FIG. 27B is a top-down view of the fourth exemplary packaging structure of FIG. 27A.

FIG. 28 is a vertical cross-sectional view of the fourth exemplary packaging structure after affixing additional threaded fasteners through the printed circuit board to the side heat sinks according to an embodiment of the present disclosure.

FIG. 29 is a first flowchart illustrating steps for forming a packaging structure according to an embodiment of the present disclosure.

FIG. 30 is a second flowchart illustrating steps for forming a packaging structure according to an embodiment of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein relate to packaging structures providing enhanced heat dissipation and structural stability. A lid structure with threaded holes is used to provide mechanical attachment of a heat sink using threaded fasteners. The heat sink provides improved thermal management by efficiently transferring heat away from semiconductor dies to provide enhanced operational reliability and performance. Various configurations for the lid structure and threaded fasteners may be used, which are now described with reference to accompanying figures.

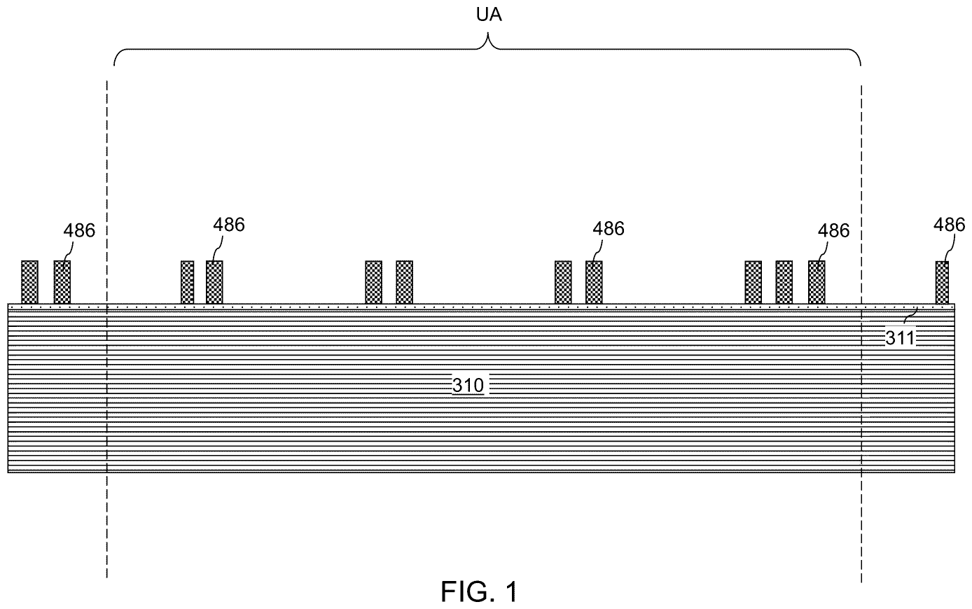

Referring to FIG. 1, an exemplary intermediate structure according to an embodiment of the present disclosure is illustrated. The intermediate structure includes a first carrier wafer 310. The first carrier wafer 310 may include an optically transparent substrate such as a glass substrate or a sapphire substrate, or may comprise a semiconductor substrate such as a silicon substrate. The diameter of the first carrier wafer 310 may be in a range from 150 mm to 450 mm, although lesser and greater diameters may be used. The thickness of the first carrier wafer 310 may be in a range from 500 microns to 2,000 microns, although lesser and greater thicknesses may also be used. Alternatively, the first carrier wafer 310 may be provided in a rectangular panel format. A first adhesive layer 311 may be applied to a front-side surface of the first carrier wafer 310. In one embodiment, the first adhesive layer 311 may be a light-to-heat conversion (LTHC) layer. Alternatively, the first adhesive layer 311 may include a thermally decomposing adhesive material.

A two-dimensional repetition of a unit via assembly may be formed over a first carrier wafer 310. Each instance of the unit via assembly may be formed within a respective unit area UA having a rectangular area. Multiple instances of the unit via assembly may be repeated along a first horizontal direction hd1 and along a second horizontal direction hd2 that is perpendicular to the first horizontal direction hd1. The unit area UA corresponds to the area of an interposer die to be subsequently formed. For example, each unit area UA may have a rectangular shape having a first side length along the first horizontal direction hd1 and having a second side length along the second horizontal direction hd2. The first side length may be the length of a pair of first sides of the rectangular shape. The second side length may be the length of a pair of second sides of the rectangular shape. The first side length is herein referred to as a first die lateral dimension dld1. The second side length is herein referred to as a second die lateral dimension dld2. Each of the first die lateral dimension dld1 and the second die lateral dimension dld2 may be independently in a range from 300 microns to 6 cm, although lesser and greater dimensions may also be used.

Generally, the TIV structures 486 may be formed over the first adhesive layer 311 by deposition and patterning of a conductive material, or by transfer from above another carrier wafer. In an illustrative example, a sacrificial matrix layer (not shown) may be formed over the first adhesive layer 311. The sacrificial matrix layer comprises a sacrificial material such as amorphous carbon, diamond-like carbon (DLC), a semiconductor material (such as amorphous silicon or a silicon-germanium alloy), or a dielectric material such as silicate glass or organosilicate glass. The thickness of the sacrificial matrix layer may be in a range from 3 microns to 60 microns, although lesser and greater thicknesses may also be used. A photoresist layer (not shown) may be applied over the sacrificial matrix layer. The photoresist layer may be lithographically pattered to form openings having a same pattern as the TIV structures 486 to be subsequently formed in a top-down view. An anisotropic etch process may be formed to transfer the pattern of the openings in the photoresist layer. Cylinder cavities may be formed through the sacrificial matrix layer underneath the openings in the photoresist layer. The photoresist layer may be removed for example, by ashing. At least one conductive material, such as at least one metallic material, may be deposited in the cylindrical cavities. For example, the at least one conductive material may comprise a conducive metallic barrier material (such as TiN, TaN, WN, or MoN) and a metallic fill material (such as W, Ti, Ta, Mo, Ru, Co, etc.). Excess portions of the at least one conductive material may be removed from above the horizontal plate including the sacrificial matrix layer. Remaining portions of the at least one conductive material that fill the cylindrical cavities comprise the TIV structures 486. Subsequently, the sacrificial matrix layer may be removed selectively to the TIV structures 486 and selectively to the first adhesive layer 311.

Alternatively, at least one conductive material layer may be deposited as a blanket material layer, i.e., as an un-patterned material layer having a uniform thickness throughout. For example, the at least one conductive material layer may comprise a conducive metallic barrier material (such as TiN, TaN, WN, or MoN) and a metallic fill material (such as W, Ti, Ta, Mo, Ru, Co, etc.). The thickness of the at least one conductive material layer may be in a range from 3 microns to 60 microns, although lesser and greater thicknesses may also be used. A photoresist layer (not shown) may be applied over the at least one conductive material layer. The photoresist layer may be lithographically patterned to form discrete photoresist material portions having a same pattern as the TIV structures 486 to be subsequently formed in a top-down view. An anisotropic etch process may be formed to transfer the pattern of the discrete photoresist material portions through the at least one conductive material layer. Patterned portions of the at least one conductive material layer comprise the TIV structures 486.

In a further alternative embodiment, the TIV structures 486 may be formed on another carrier wafer, and may be attached to the top surface of the first adhesive layer 311. The TIV structures 486 may be subsequently detached from the additional carrier wafer.

In one embodiment, the pattern of the TIV structures 486 within each unit area UA may be a pattern that is derived from a rectangular periodic array having a first pitch along the first horizontal direction hd1 and having a second pitch along the second horizontal direction hd2 by omitting a subset of the TIV structures 486. Specifically, omission of the subset of the TIV structures 486 may be made such that two rectangular corner regions are free of the TIV structures 486 and at least one center region is free of the TIV structures 486. The at least one center region corresponds to at least one area in which at least one local silicon interconnect (LSI) bridge is to be positioned. In one embodiment, each of the TIV structures 486 comprises a metallic via structure.

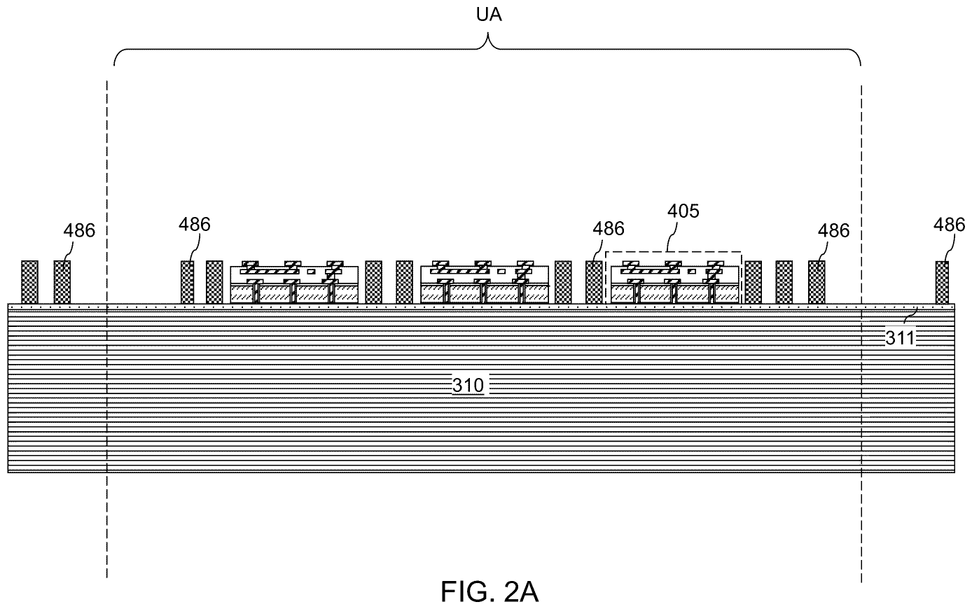

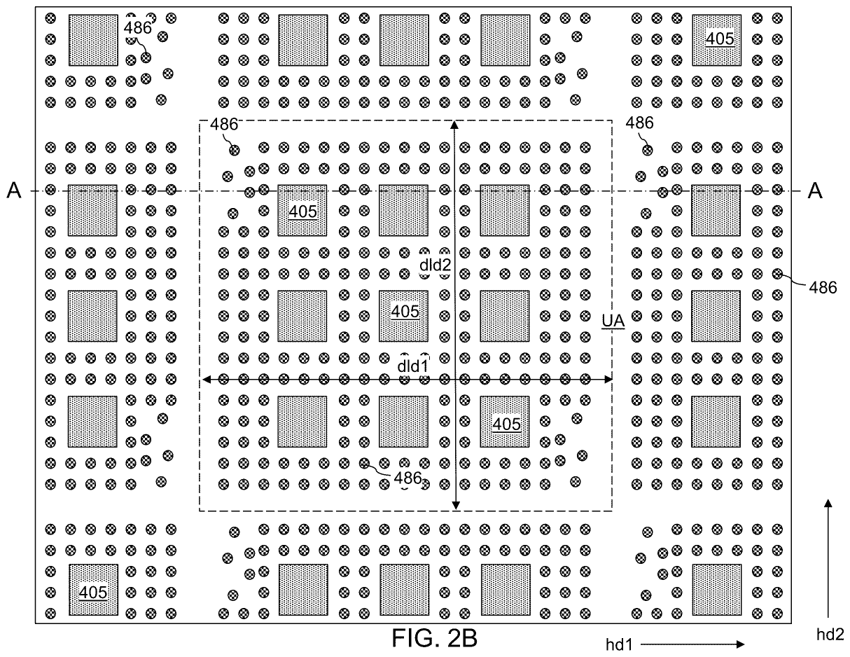

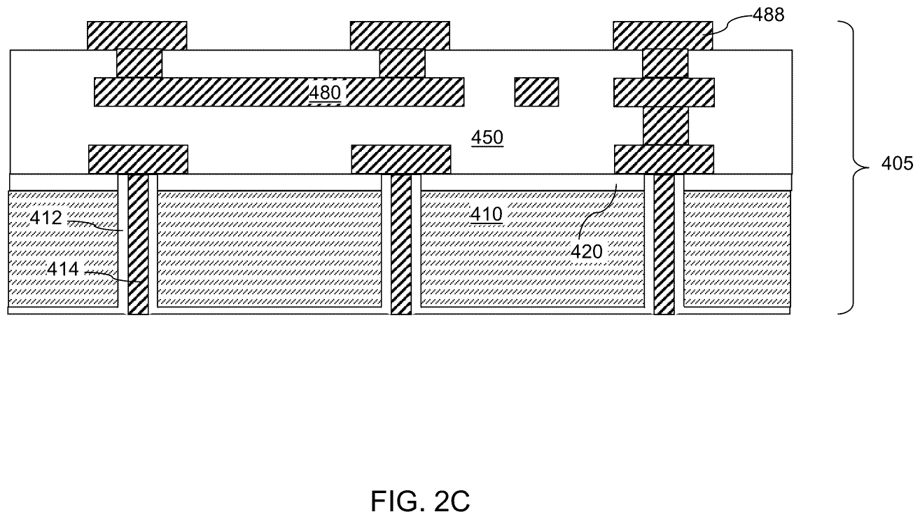

Referring to FIGS. 2A-2C, a plurality of local silicon interconnect (LSI) bridges 405 may be provided. Each LSI bridge 405 includes a silicon substrate 410 (as thinned and diced during manufacturing of the local silicon interconnect bridge 405), through-silicon via structures 414 vertically extending through the silicon substrate 410, through-substrate openings that vertically extend through the silicon substrate 410, a dielectric liner 412 that provides electrical isolation for the through-silicon via structures 414, backside dielectric material layer 420, and metal interconnect structures 480 embedded in dielectric material layers 450 and electrically connected to the through-silicon via structures 414 and/or electrically connected to one another. Metal pads, which are herein referred to as LSI metal pads 488, may be provided on the topmost metal interconnect structures 480.

The LSI bridges 405 may be placed within openings in the arrays of the TIV structures 486 on the top surface of the first adhesive layer 311. Generally, a pick and place tool may be used to place at least one LSI bridge 405 within each unit area UA. At least one local silicon interconnect (LSI) bridge 405 may be placed within each unit area UA of repetition using the pick and place tool. In one embodiment, a plurality of LSI bridges 405 may be placed within each unit area UA of repetition using the pick and place tool.

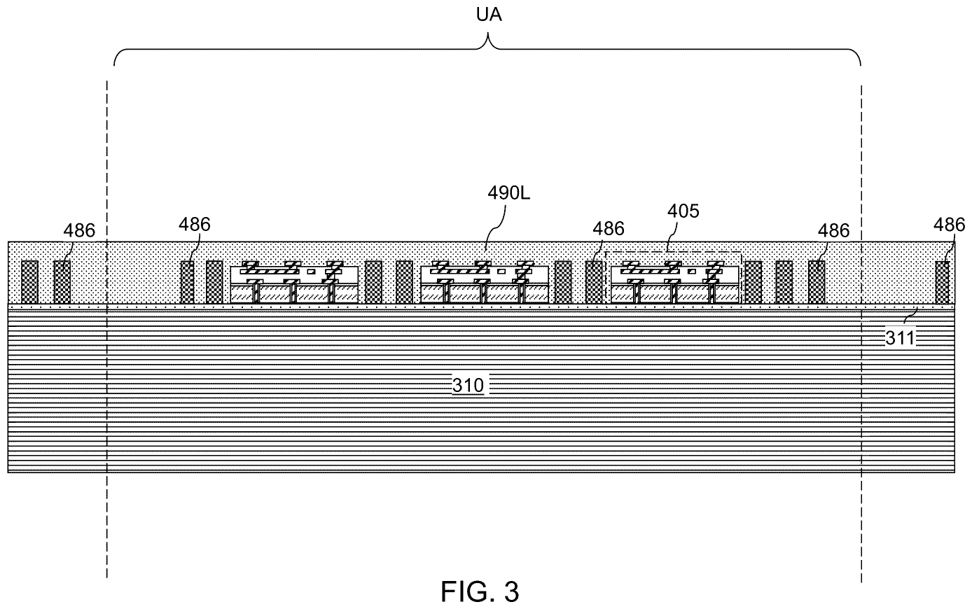

Referring to FIG. 3, an encapsulant, such as a molding compound (MC) may be applied to the gaps within the assembly of the LSI bridges 405 and the TIV structures 486. The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability.

The MC may be cured at a curing temperature to form an MC matrix, which is herein referred to as a first molding compound (MC) material layer or an interposer-level molding compound (MC) material layer 490L. The interposer-level MC material layer 490L laterally encloses each of the LSI bridges 405 and the TIV structures 486. The interposer-level MC material layer 490L may be a continuous material layer that extends across the entirety of the area of a reconstituted wafer overlying the first carrier wafer 310.

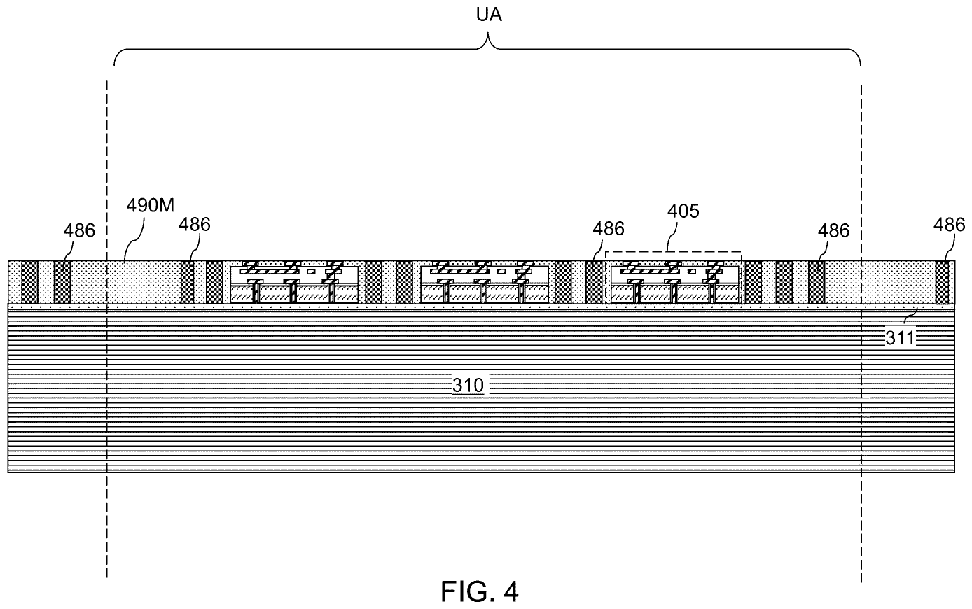

Referring to FIG. 4, excess portions of the interposer-level MC material layer 490L are removed from above the horizontal plane including the top surfaces of the LSI bridge 405 and the TIV structures 486 by a planarization process, which may use chemical mechanical planarization (CMP). Surfaces of the through-silicon via structures 414 may be physically exposed after the planarization process. The remaining portion of the interposer-level MC material layer 490L is herein referred to as an interposer-level molding compound (MC) matrix 490M.

The interposer-level MC matrix 490M includes a plurality of molding compound (MC) interposer frames located within a respective unit area UA and are laterally adjoined to one another. Each MC interposer frame corresponds to a portion of the interposer-level MC matrix 490M located within a unit area UA, i.e., an area of a single interposer to be subsequently formed. Each MC interposer frame laterally surrounds a respective set of at least one LSI bridge 405 and a respective array of TIV structures 486.

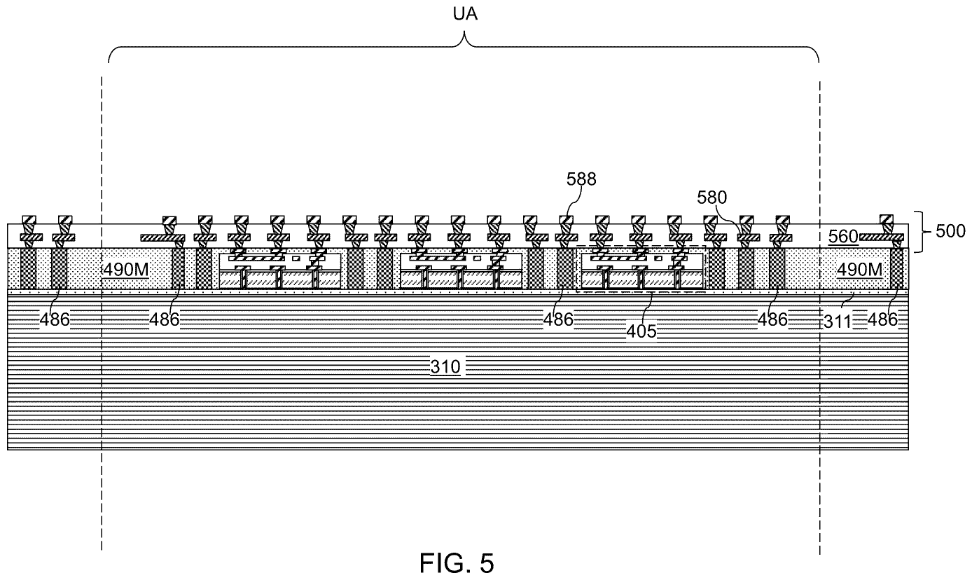

Referring to FIG. 5, a first redistribution structure 500 may be formed on a top side of the two-dimensional repetition of the unit via assembly and the interposer-level MC matrix 490M. The first redistribution structure 500 comprises first redistribution wiring interconnects 580, first redistribution dielectric layers 560, and first bonding structures 588.

The first redistribution dielectric layers 560 include a respective dielectric polymer material such as polyimide (PI), benzocyclobutene (BCB), or polybenzobisoxazole (PBO). Each first redistribution dielectric layer 560 may be formed by spin coating and drying of the respective dielectric polymer material. The thickness of each first redistribution dielectric layer 560 may be in a range from 2 microns to 40 microns, such as from 4 microns to 20 microns. Each first redistribution dielectric layer 560 may be patterned, for example, by applying and patterning a respective photoresist layer thereabove, and by transferring the pattern in the photoresist layer into the first redistribution dielectric layer 560 using an etch process such as an anisotropic etch process. The photoresist layer may be subsequently removed, for example, by ashing.

Each of the first redistribution wiring interconnects 580 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the first redistribution wiring interconnects 580 may include copper, nickel, or copper and nickel. The thickness of the metallic fill material that is deposited for each first redistribution wiring interconnect 580 may be in a range from 2 microns to 40 microns, such as from 4 microns to 10 microns, although lesser or greater thicknesses may also be used. The total number of levels of wiring in the first redistribution structure 500 (i.e., the levels of the first redistribution wiring interconnects 580) may be in a range from 1 to 10.

The first bonding structures 588 may comprise microbump structures that may be subsequently used to attach semiconductor dies. The metallic fill material for the microbump structures may include copper. The first bonding structures 588 may have horizontal cross-sectional shapes of rectangles, rounded rectangles, or circles. Other horizontal cross-sectional shapes may be within the contemplated scope of disclosure. In some embodiments, the first bonding structures 588 may be configured for microbump bonding, and may have a thickness in a range from 5 microns to 100 microns, although lesser or greater thicknesses may also be used. In one embodiment, the first bonding structures 588 within each unit area UA may be formed as at least one array of microbumps (such as copper pillars). Each of the microbumps may have a lateral dimension in a range from 10 microns to 50 microns, and may have a pitch in a range from 20 microns to 100 microns.

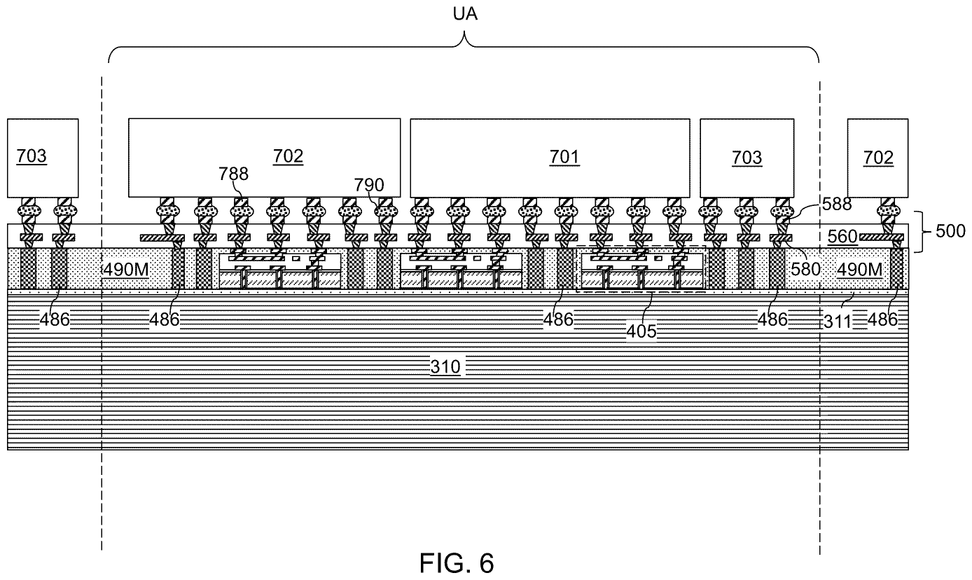

Referring to FIG. 6, a set of at least one semiconductor die (701, 702, 703) may be bonded to a respective set of first bonding structures 588 within each unit area UA. Each set of at least one semiconductor die (701, 702, 703) includes at least one semiconductor die, and may comprise a plurality of semiconductor dies (701, 702, 703). For example, each set of at least one semiconductor die (701, 702, 703) may include at least one system-on-chip (SoC) die (701, 702) and/or at least one memory die 703. Each SoC die (701, 702) may comprise an application processor die, a central processing unit die, or a graphic processing unit die. In one embodiment, the at least one memory die 703 may comprise a high bandwidth memory (HBM) die that includes a vertical stack of static random access memory dies. In one embodiment, the at least one semiconductor die (701, 702, 703) may include at least one system-on-chip (SoC) die (701, 702) and at least one high bandwidth memory (HBM) die. Each HBM die may comprise a vertical stack of static random access memory (SRAM) dies that are interconnected to one another through arrays of microbumps and are laterally surrounded by a respective molding material enclosure frame.

Each semiconductor die (701, 702, 703) may comprise a respective array of on-die bump structures 788. Solder material portions may be applied to the on-die bump structures 788 of the semiconductor dies (701, 702, 703), or may be applied to the first bonding structures 588. The solder material portions are herein referred to as die-interposer-bonding (DIB) solder material portions 790, or as first solder material portions. Each of the semiconductor dies (701, 702, 703) may be positioned in a face-down position such that on-die bump structures 788 face the first bonding structures 588. Placement of the semiconductor dies (701, 702, 703) may be performed using a pick and place apparatus such that each of the on-die bump structures 788 may face a respective one of the first bonding structures 588. Each set of at least one semiconductor die (701, 702, 703) may be placed within a respective unit area. A DIB solder material portion 790 is attached to one of the on-die bump structure 788 and the first bonding structure 588 for each facing pair of an on-die bump structure 788 and a first bonding structure 588.

In one embodiment, the on-die bump structures 788 and the first bonding structures 588 may be configured for microbump bonding. In this embodiment, each of the on-die bump structures 788 and the first bonding structures 588 may be configured as copper pillar structures having a diameter in a range from 10 microns to 50 microns, and may have a respective height in a range from 5 microns to 100 microns. The pitch of the microbumps in the direction of periodicity may be in a range from 20 microns to 100 microns, although lesser and greater pitches may also be used. Upon reflow, the lateral dimensions of each DIB solder material portion 790 may be in a range from 100% to 150% of the lateral dimension (such as a diameter) of the adjoined on-die bump structure 788 or of the adjoined first bonding structure 588.

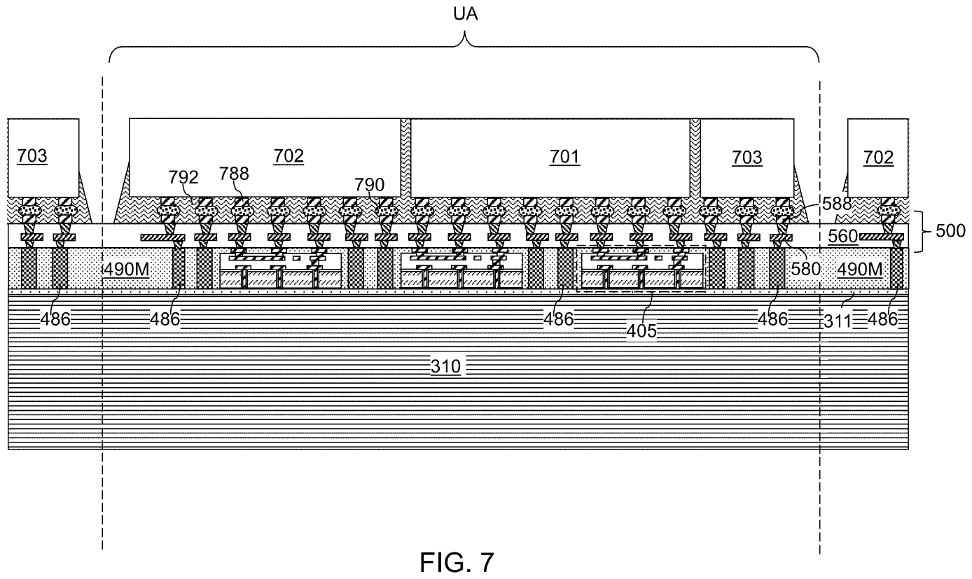

Referring to FIG. 7, a die-side underfill material may be applied into each gap between the first redistribution structure 500 and a respective set of at least one semiconductor die (701, 702, 703). The die-side underfill material may comprise any underfill material known in the art. A die-side underfill material portion 792 may be formed within each unit area UA between the first redistribution structure 500 and the respective set of at least one semiconductor die (701, 702, 703). The die-side underfill material portions 792 may be formed by injecting the die-side underfill material around a respective array of DIB solder material portions 790 in a respective unit area UA. Any known underfill material application method may be used, which may be, for example, the capillary underfill method, the molded underfill method, or the printed underfill method.

A die-side underfill material portion 792 may laterally surround, and contact, a respective set of the DIB solder material portions 790 within the unit area UA. The die-side underfill material portion 792 may be formed around, and contact, the DIB solder material portions 790, the first bonding structures 588, and the on-die bump structures 788 in the unit area. Generally, at least one semiconductor die (701, 702, 703) comprising a respective set of on-die bump structures 788 is attached to the first redistribution structure 500 through a respective set of DIB solder material portions 790 within each unit area UA.

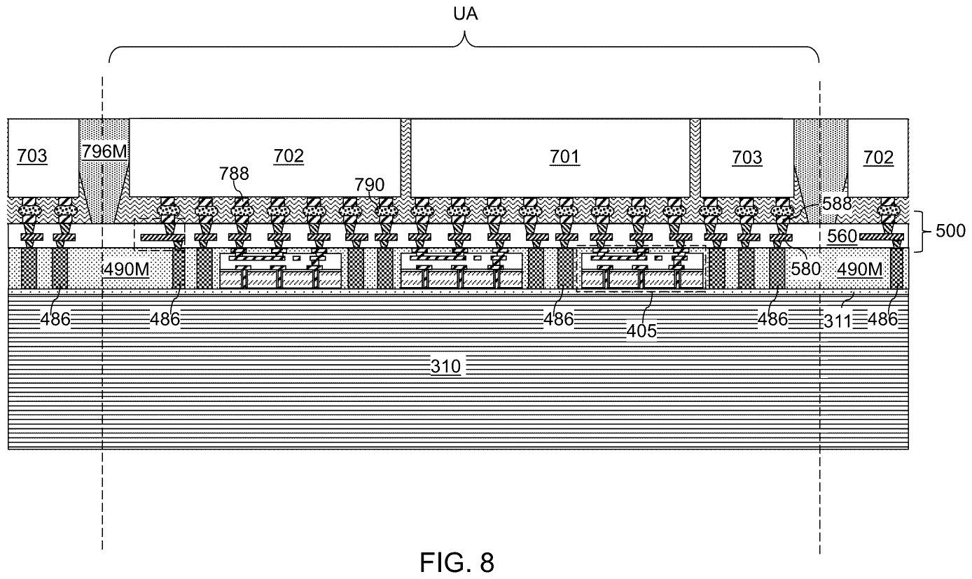

Referring to FIG. 8, a molding compound (MC) may be applied to the gaps between assemblies of a respective set of semiconductor dies (701, 702, 703) and a respective die-side underfill material portion 792. The MC may include any material that may be used for the interposer-level MC matrix 490M discussed above. The MC may include epoxy resin, hardener, silica (as a filler material), and other additives. The MC may be cured at a curing temperature to form an MC matrix, which is herein referred to as a die-level MC matrix 796M or as a second MC matrix. The die-level MC matrix 796M laterally surrounds and embeds each assembly of a set of semiconductor dies (701, 702, 703) and a die-side underfill material portion 792. The die-level MC matrix 796M includes a plurality of molding compound (MC) die frames that are laterally adjoined to one another. Each MC die frame is a portion of the die-level MC matrix 796M that is located within a respective unit area UA. Thus, each MC die frame laterally surrounds, and embeds, a respective a set of semiconductor dies (701, 702, 703) and a respective die-side underfill material portion 792. Young's modulus of pure epoxy is about 3.35 GPa, and Young's modulus of the MC may be higher than Young's modulus of pure epoxy due to additives therein. Thus, Young's modulus of the die-level MC matrix 796M may be greater than 3.5 GPa.

Portions of the die-level MC matrix 796M that overlies the horizontal plane including the top surfaces of the semiconductor dies (701, 702, 703) may be removed by a planarization process. For example, the portions of the die-level MC matrix 796M that overlies the horizontal plane may be removed using a chemical mechanical planarization (CMP). The reconstituted wafer that overlies the first carrier wafer 310 comprises a combination of the die-level MC matrix 796M, the semiconductor dies (701, 702, 703), the die-side underfill material portions 792, the first redistribution structure 500, a two-dimensional array of combinations of at least one LSI bridge 405, and the TIV structures 486. Each portion of the die-level MC matrix 796M located within a unit area UA constitutes an MC die frame.

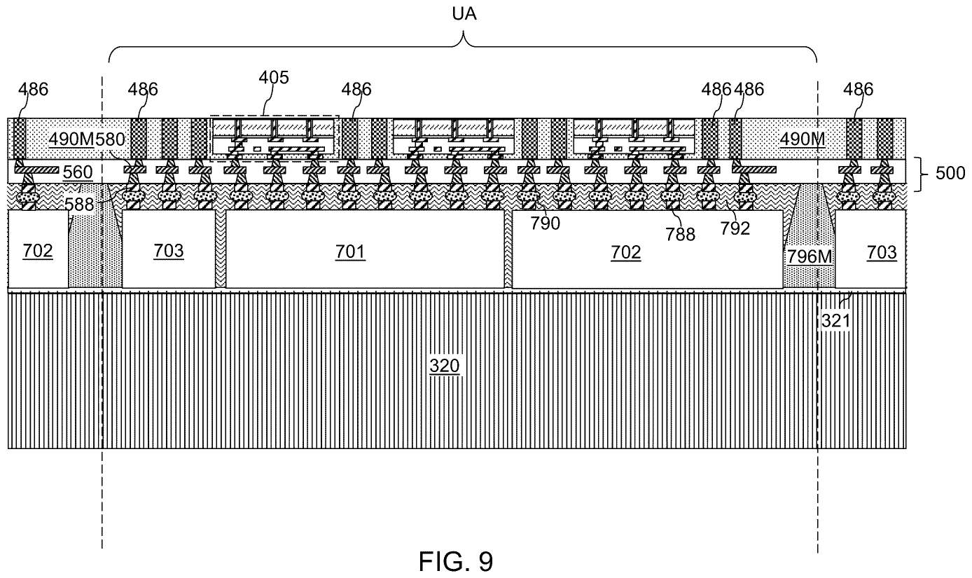

Referring to FIG. 9, a second adhesive layer 321 may be applied over the die-level MC matrix 796M. The second adhesive layer 321 may comprise a light-to-heat conversion (LTHC) layer or a thermally decomposing adhesive material layer depending on the removal mechanism to be subsequently used. A second carrier wafer 320 may be attached to the die-level MC matrix 796M and the semiconductor dies (701, 702, 703) through the second adhesive layer 321. The second carrier wafer 320 may comprise any material that may be used for the first carrier wafer 310, and generally may have about the same thickness range as the first carrier wafer 310.

The first carrier wafer 310 may be detached from the reconstituted wafer. In some embodiments, the first carrier wafer 310 and the first adhesive layer 311 may be removed by backside grinding. Optionally, at least one selective etch process (such as a wet etch process or a reactive ion etch process) may be used in conjunction with the backside grinding process to minimize collateral removal of surface portions of the LSI bridges 405, and the TIV structures 486. Alternatively or additionally, in embodiments in which the first carrier wafer 310 includes an optically transparent material and the first adhesive layer 311 comprises a light-to-heat conversion material, irradiation through the first carrier wafer 310 may be used to detach the first carrier wafer 310. In embodiments in which the first adhesive layer 311 comprises a thermally decomposable adhesive material, an anneal process or a laser irradiation may be used to detach the first carrier wafer 310. A suitable clean process may be performed to remove residual portions of the first adhesive layer 311.

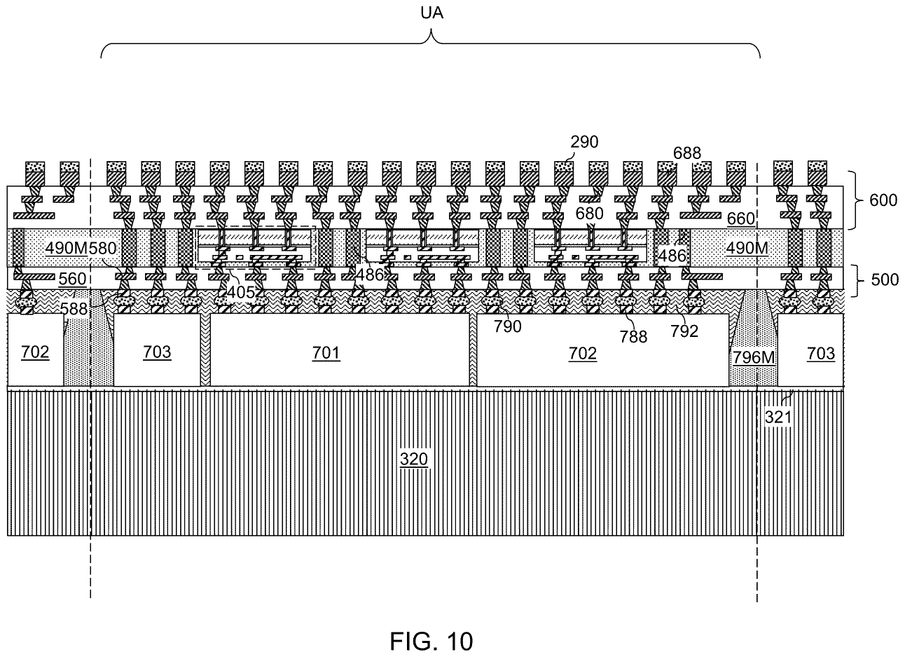

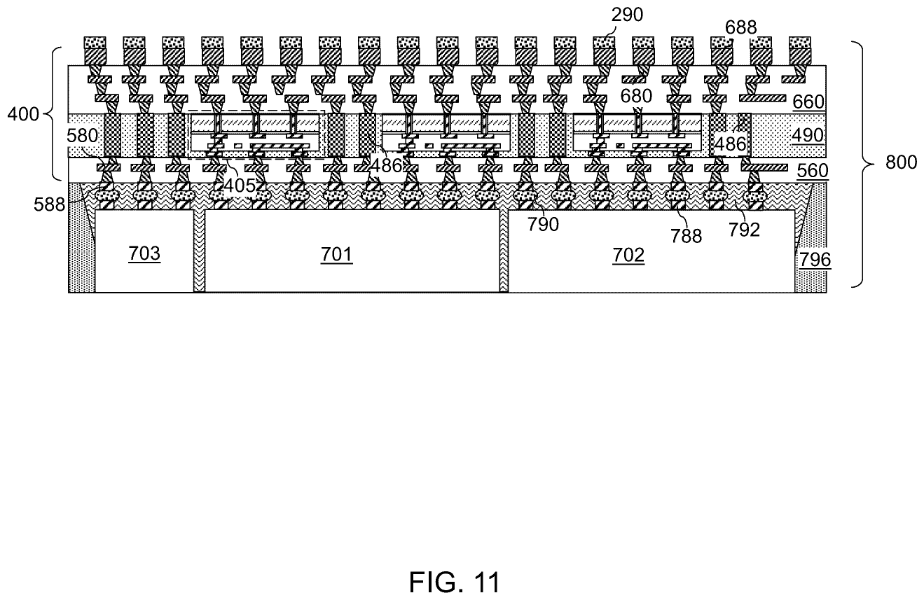

Referring to FIG. 10, a second redistribution structure 600 may be formed on a physically exposed side of the two-dimensional repetition of the unit via assembly and the interposer-level MC matrix 490M. The second redistribution structure 600 comprises second redistribution wiring interconnects 680, optional second interconnect-level alignment structures (not shown), second redistribution dielectric layers 660, and second bonding structures 688. Generally, the second redistribution structure 600 may be formed in the same manner as the first redistribution structures 500 with suitable changes in the lithographic pattern and/or in the thicknesses and material compositions of material layers. The second bonding structures 688 may be formed as bonding pads that are configured for controlled collapse chip connection (C4) bonding.

Referring to FIG. 11, the second carrier wafer 320 may be detached from the reconstituted wafer. In embodiments in which the second carrier wafer 320 includes an optically transparent material and the second adhesive layer 321 comprises a light-to-heat conversion material, irradiation through the second carrier wafer 320 may be used to detach the second carrier wafer 320. In embodiments in which the second adhesive layer 321 comprises a thermally decomposable adhesive material, an anneal process or a laser irradiation may be used to detach the second carrier wafer 320. A suitable clean process may be performed to remove residual portions of the second adhesive layer 321. A horizontal surface of the die-level MC matrix 796M may be physically exposed.

The reconstituted wafer includes a two-dimensional array of composite packages 400, and further includes a two-dimensional array of sets of at least one semiconductor die (701, 702, 703) that are bonded to a respective composite package 400. The reconstituted wafer may be diced along dicing channels (which correspond to the dicing lines DL described above) by performing a dicing process. The dicing channels correspond to the boundaries between neighboring pairs of unit areas UA. Each diced unit from the reconstituted wafer comprises a fan-out package 800. Each diced portion of the die-level MC matrix 796M constitutes a die-level MC frame 796. Each diced portion of the interposer-level MC matrix 490M constitutes an interposer-level MC frame 490.

The diced portions of the reconstituted wafer comprise fan-out packages 800. Each fan-out package 800 comprises at least one semiconductor die (701, 702, 703), a composite package 400, a die-side underfill material portion 792, a die-level MC frame 796, and at least one array of DIB solder material portions 790. Each composite package 400 comprises a unit via assembly including TIV structures 486, at least one LSI bridge 405, an interposer-level MC frame 490, a first redistribution structure 500, and a second redistribution structure 600.

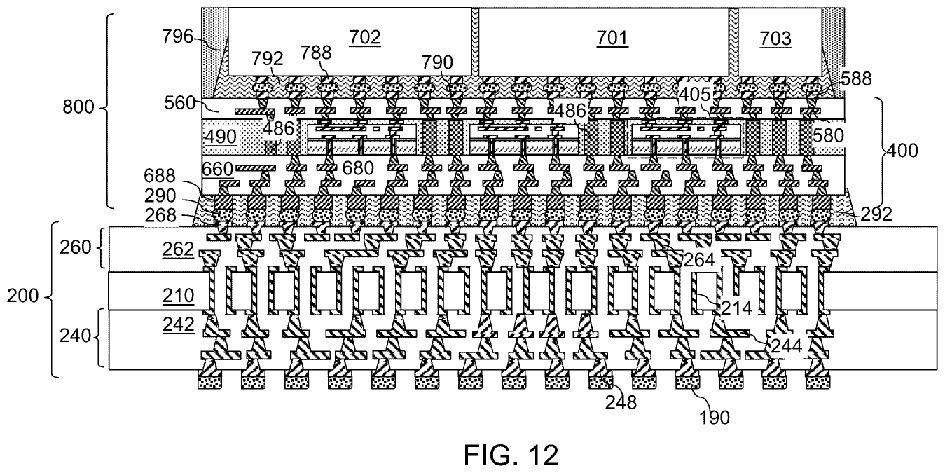

Referring to FIG. 12, a packaging substrate 200 may be bonded to the fan-out package 800. The packaging substrate 200 may be a cored packaging substrate including a core substrate 210, or a coreless packaging substrate that does not include a package core. Alternatively, the packaging substrate 200 may include a system-on-integrated packaging substrate (SoIS) including redistribution layers. dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. While the present disclosure is described using a cored packaging substrate, the scope of the present disclosure is not limited by any particular type of substrate package. For example, an SoIS may be used in lieu of a cored packaging substrate. In embodiments in which SoIS is used, the core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners (not illustrated) may be used to electrically isolate the through-core via structures 214 from the core substrate 210.

The packaging substrate 200 may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In one embodiment, the chip-side surface laminar circuit 260 comprises chip-side wiring interconnects 264 that are connected to an array of substrate bonding pads 268. The array of substrate bonding pads 268 may be configured to allow bonding through C4 solder balls. The board-side surface laminar circuit 240 comprises board-side wiring interconnects 244 that are connected to an array of board-side bonding pads 248. The array of board-side bonding pads 248 is configured to allow bonding through solder material portions having a greater dimension than the C4 solder balls. While the present disclosure is described using an embodiment in which the packaging substrate 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

The fan-out package 800 may be attached to the packaging substrate 200 using the second solder material portions, which are herein referred to interposer-substrate-bonding (ISB) solder material portions 290. Specifically, each of the ISB solder material portions 290 may be bonded to a respective one of the substrate bonding pads 268 and to a respective one of the second bonding structures 688 located on the composite package 800. A reflow process may be performed to reflow the ISB solder material portions 290 such that each ISB solder material portion 290 may be bonded to a respective one of the substrate bonding pads 268 and to a respective one of the second bonding structures 688.

An underfill material may be applied into a gap between the composite package 800 and the packaging substrate 200. The underfill material may comprise any underfill material known in the art. An underfill material portion may be formed around the ISB solder material portions 290 in the gap between the composite package 800 and the packaging substrate 200. This underfill material portion is herein referred to as an interposer-substrate underfill material portion 292, or as an IP underfill material portion 292. An array of solder material portions 190 may be formed on the array of board-side bonding pads 248. A bonded assembly (800, 200) including a composite package 800 and a packaging substrate 200 may be formed.

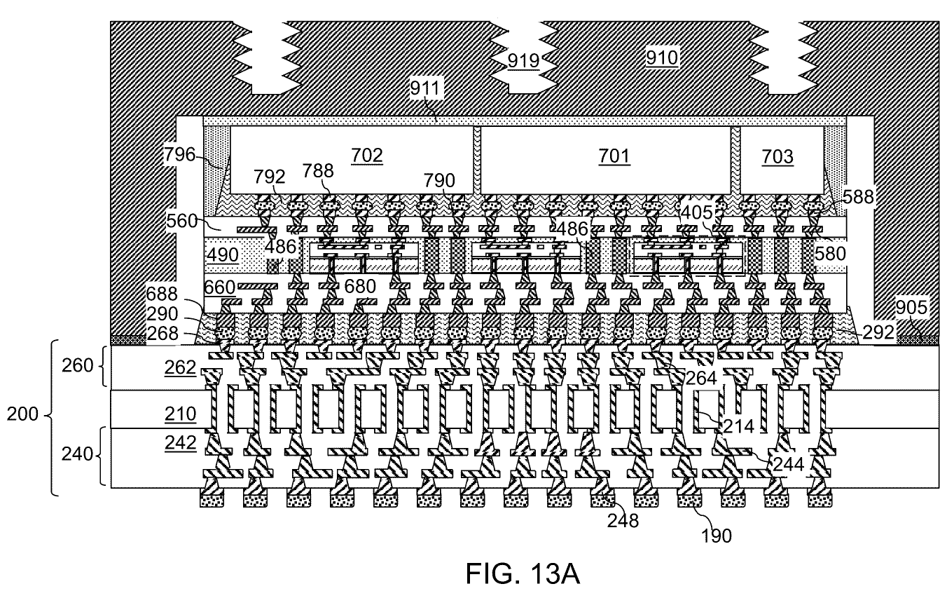

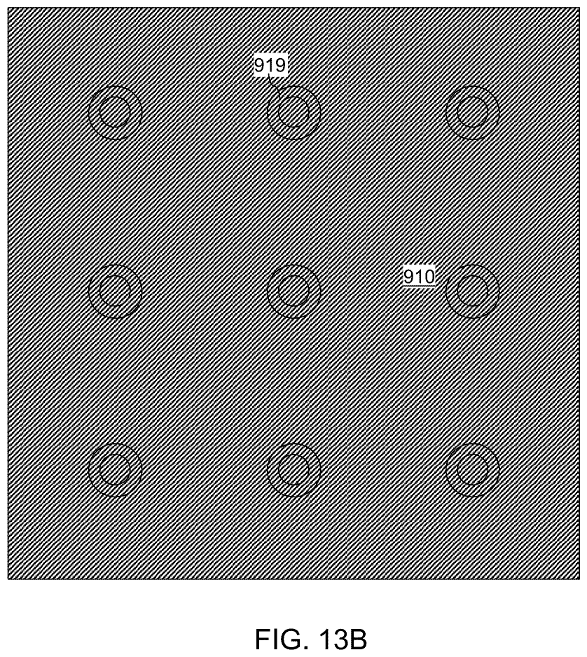

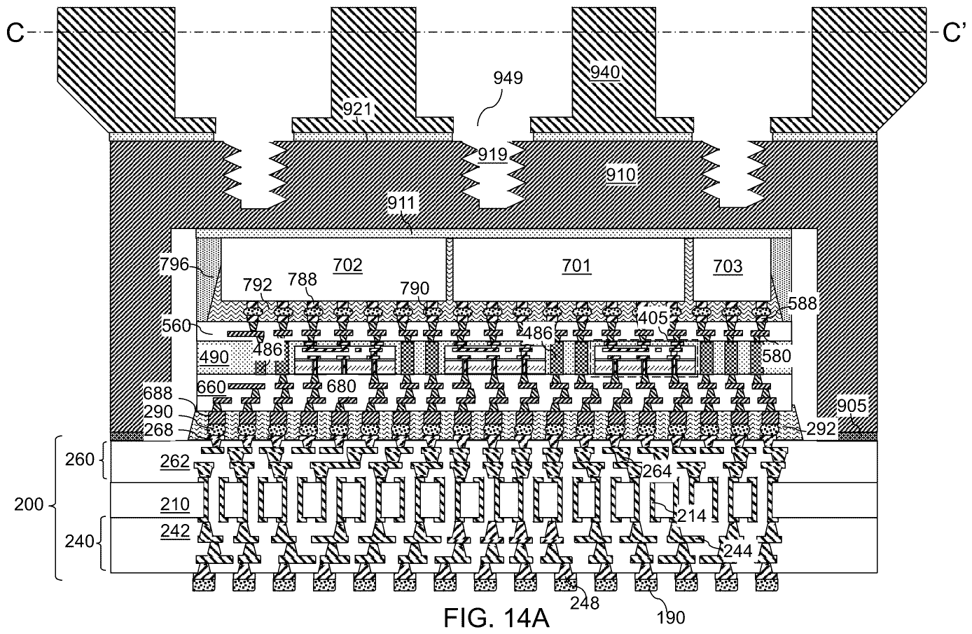

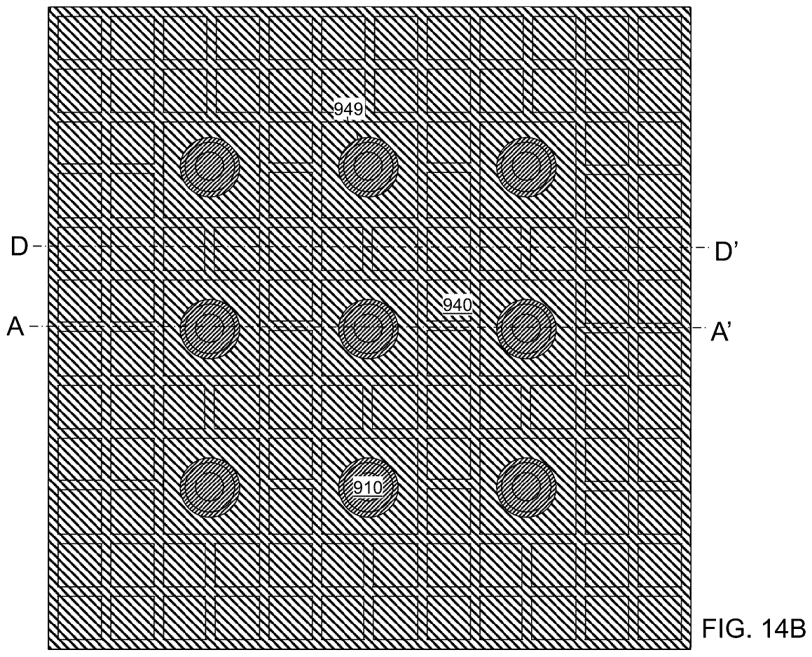

Referring to FIGS. 13A and 13B, a lid structure 910 may be attached to the bonded assembly (800, 200) to form a first exemplary packaging structure. The lid structure 910 may comprise a metallic material (such as Cu) or a dielectric material providing high thermal conductivity (such as aluminum nitride). According to an aspect of the present disclosure, the lid structure 910 comprises at least one threaded hole 919 vertically extending downward from a top surface of the lid structure 910 toward the bonded assembly (800, 200). The vertical extent of the at least one threaded hole 919 may be in a range from 1 mm to 10 mm, such as from 2 mm to 5 mm, although lesser or greater vertical extents may also be used. The at least one threaded hole 919 may comprise a plurality of threaded holes 919, which may be an array of threaded holes 919. As used herein, a threaded hole refers to a hole with threads along its sidewall for mating with a threaded fastener such as a bolt or a screw. In one embodiment, the lid structure 910 may comprise a horizontally-extending plate portion and vertically-extending wall portions. The at least one threaded hole 919 may be formed within the horizontally-extending plate portion of the lid structure 910. The depth of the at least one threaded hole 919 may be in a range from 30% to 99%, such as from 50% to 90%, of the thickness of the horizontally-extending plate portion of the lid structure 910.

The lid structure 910 may be attached to the bonded assembly (800, 200) comprising at least one semiconductor die (701, 702, 703) using an adhesive layer 905 and a first thermal interface material layer 911. The lid structure 910 may be attached to the bonded assembly (800, 200) using an adhesive layer 905 that bonds the lid structure 910 to the packaging substrate 200. In one embodiment, the adhesive layer 905 may be applied to a first element selected from the packaging substrate 200 and the lid structure 910, and a second element selected from the packaging substrate 200 and the lid structure 910 and different from the first element may be brought into contact with the adhesive layer 905. In an illustrative example, the adhesive layer 905 may be applied to a peripheral portion of the top surface of the packaging substrate 200. In the illustrated example, the adhesive layer 905 is applied between the packaging substrate 200 and a frame-shaped bottom surface of the lid structure 910.

A first thermal interface material (TIM) layer 911 may be applied to the top surface of the composite package 800 prior to attaching the lid structure 910 to the packaging substrate 200. The first TIM layer 911 may comprise any thermal interface material known in the art. The first TIM layer 911 may be applied to each top surface of the at least one semiconductor die (701, 702, 703). Upon bonding the lid structure 910 to the bonded assembly (800, 200) through the adhesive layer 905, the first TIM layer 911 may contact the bottom surface of the horizontally-extending plate portion of the lid structure 910. In one embodiment, the contact area between the first TIM layer 911 and the bottom surface of the horizontally-extending plate portion of the lid structure 910 may be the same as, or may be about the same as, the area of the top surface of the composite package 800.

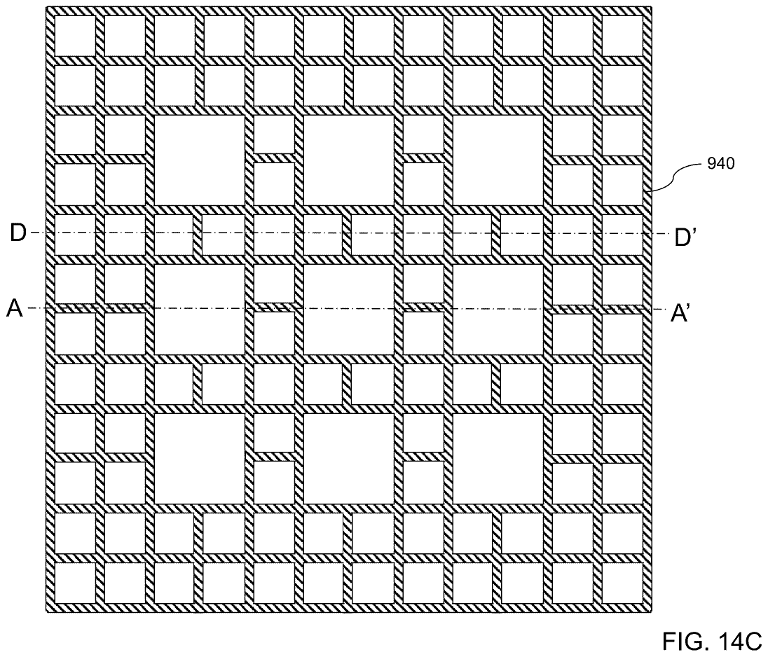

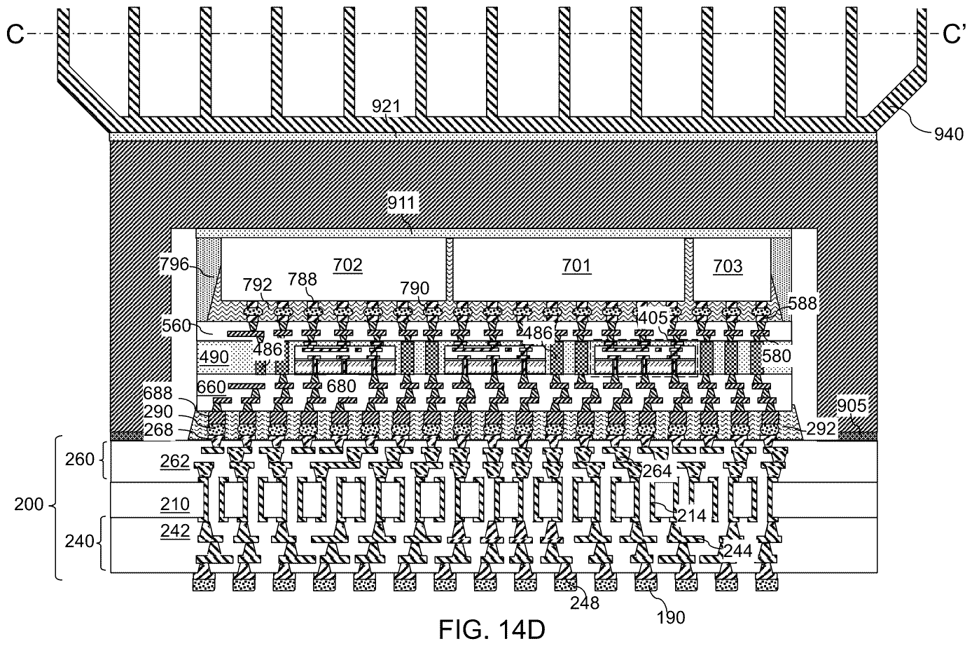

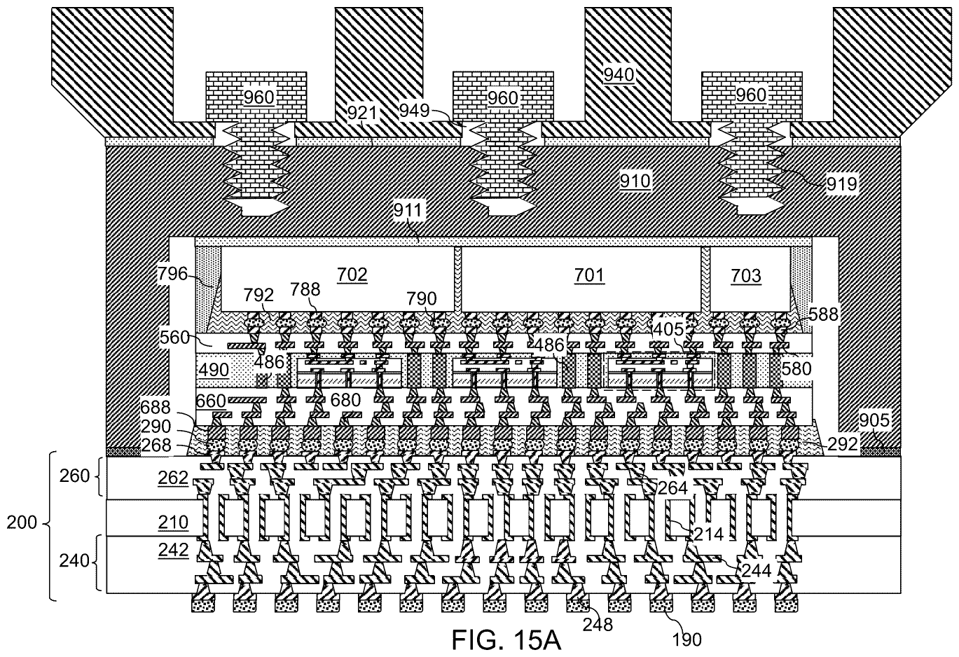

Referring to FIGS. 14A-14D, a heat sink 940 comprising at least one through-hole 949 may be provided. The heat sink 940 comprises a metallic material providing high electrical conductivity such as copper or aluminum. According to an aspect of the present disclosure, the configuration of the at least one through-hole 949 through the heat sink 940 may be selected to match the pattern of the at least one threaded hole 919 in the lid structure 910. In embodiments in which the at least one threaded hole 919 comprises a plurality of threaded holes 919, the at least one through-hole 949 may comprise a plurality of through-holes 949. Generally, the sidewall(s) of the at least one through-hole 949 may be smooth, and the lateral dimensions (such as the diameters) of the at least one through-hole 949 may be selected to allow unobstructed passage of threaded fasteners to be subsequently used.

The heat sink 940 may be attached to the lid structure 910 using a second thermal interface material (TIM) layer 921. The second TIM layer 921 may comprise any thermal interface material known in the art. The thermal interface material of the second TIM layer 921 may be applied in areas that do not overlap with the at least one threaded hole 919. Thus, the second TIM layer 921 comprises at least one perforation therethrough such that the pattern of the at least one perforation matches the pattern of the at least one threaded hole 919. In other words, the second TIM layer 921 does not have any areal overlap with the at least one threaded hole 919.

The heat sink 940 may comprise a horizontally-extending heat sink plate portion in contact with the second TIM layer 921 and a plurality heat sink fin portions that extend vertically upward from the horizontally-extending heat sink plate portion. In some embodiments, the plurality of heat sink fin portions may be arranged as a grid pattern. According to an embodiment of the present disclosure, the pattern of the plurality of heat sink fin portions is selected to contain an opening over each of the at least one through-hole 949, which extends through the horizontally-extending heat sink plate portion of the heat sink 940. Each opening in the plurality of heat sink fin portions function as a keep-out zone which prevents formation of any physical structure that may hinder application of a threaded fastener in a subsequent processing step.

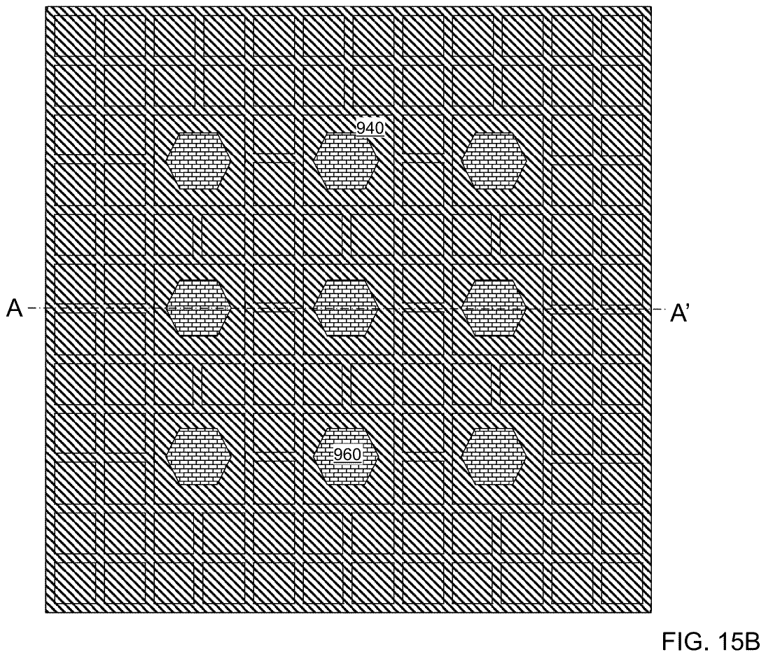

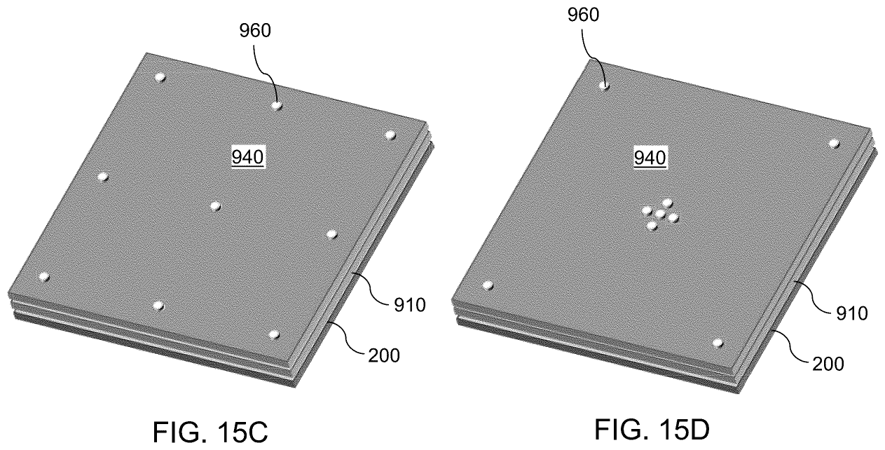

Referring to FIGS. 15A and 15B, the heat sink 940 may be affixed to the lid structure 910 using at least one threaded fastener 960. In other words, the at least one threaded fastener 960 may be used to mount the heat sink 940 to the lid structure 910. The at least one threaded fastener 960 may comprise a plurality of threaded fasteners 960. Each of the at least one threaded fastener 960 may be passed through a respective one of the at least one through-hole 949. Each of the at least one threaded fastener 960 may be engaged into a respective one of the at least one threaded hole 919 so that the heat sink 940 is affixed to the lid structure 910. In embodiments in which the at least one threaded fastener 960 comprises at least one bolt, each of the at least one threaded fastener 960 may fit into a respective threaded hole 919 in the lid structure 910 without changing the shape of the respective threaded hole 919. In embodiments in which the at least one threaded fastener 960 comprises at least one screw, each of the at least one threaded fastener 960 may fit into a respective threaded hole 919 while deforming the respective threaded hole 919.

Generally, the heat sink 940 may be mounted to the lid structure 910 using at least one threaded fastener 960. The at least one threaded fastener 960 is a mechanical structure that provides mechanical attachment between the heat sink 940 and the lid structure 910 irrespective of the deformation that may occur in the lid structure 910 and/or in the heat sink 940 during operation of the packaging structure. Thus, the at least one threaded fastener 960 provides mechanically stable attachment that is not affected by thermal expansion of the lid structure 910, the first TIM layer 911, the second TIM layer 921, and the heat sink 940. The heat sink 940 comprises at least one through-hole 949 through which the at least one threaded fastener 960 passes, and the at least one threaded fastener 960 is threaded into a respective one of the at least one threaded hole 919.

FIGS. 15C and 15D illustrate alternative configurations of the first exemplary structure at the processing steps of FIGS. 15A and 15B. Generally, the locations of the at least one threaded fastener 960 may be distributed over the entire area of the lid structure 910 provided that the at least one threaded fastener 960 may provide reliable structural fastening between the heat sink and the lid structure 910. FIG. 15C illustrates a first configuration in which a 3×3 array of threaded fasteners 960 is used such that 8 threaded fasteners 960 are located along the edges of the lid structure 910, and one threaded fastener 960 is located at the center of the lid structure 910. FIG. 15D illustrates a second configuration in which four threaded fasteners 960 are used at four corners of the lid structure 910, and a cluster of additional threaded fasteners 960 are provided at the center of the lid structure 960.

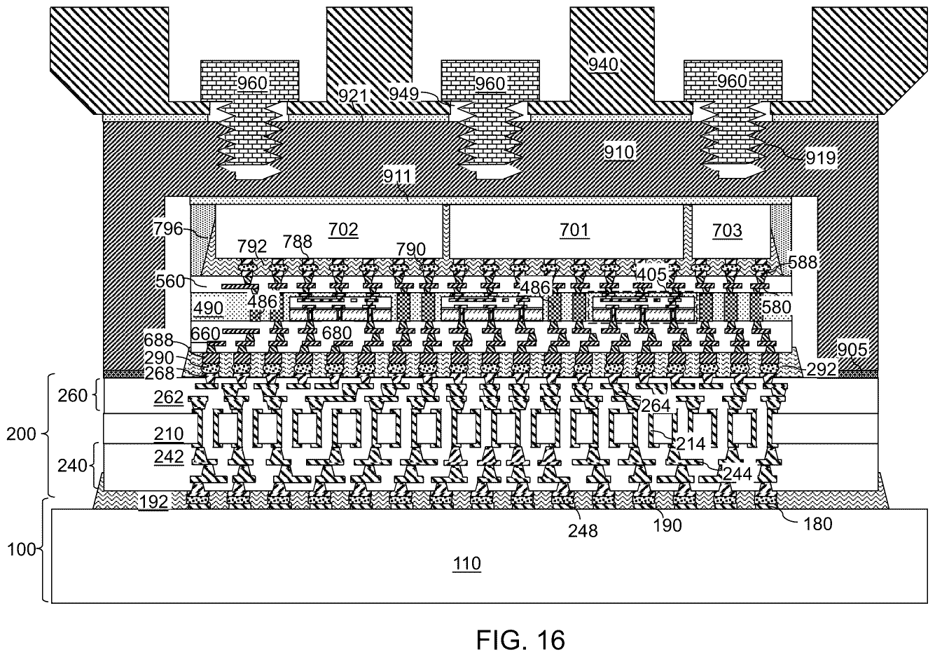

Referring to FIG. 16, a printed circuit board (PCB) 100 including a PCB substrate 110 and PCB bonding pads 180 may be provided. The PCB 100 includes a printed circuitry (not shown) at least on one side of the PCB substrate 110. The printed circuit board 100 may be attached to the bonded assembly of the composite package 800, the packaging substrate 200, the lid structure 910, and the heat sink 940. In one embodiment, the bonded assembly (800, 200) is attached to the printed circuit board 100 using an array of solder material portions 190 that provides solder bonding between the printed circuit board 100 and the packaging substrate 200. In this embodiment, the array of solder material portions 190 may be disposed over the array of PCB bonding pads 180, and may be reflowed to form solder joints that are bonded to a respective pair of a board-side bonding pad 248 and a PCB bonding pad 180. An additional underfill material portion, which is herein referred to as a board-substrate underfill material portion 192 or a BS underfill material portion 192, may be formed around the solder material portions 190 by applying and shaping an underfill material. The packaging substrate 200 is attached to the PCB 100 through the array of solder material portions 190.

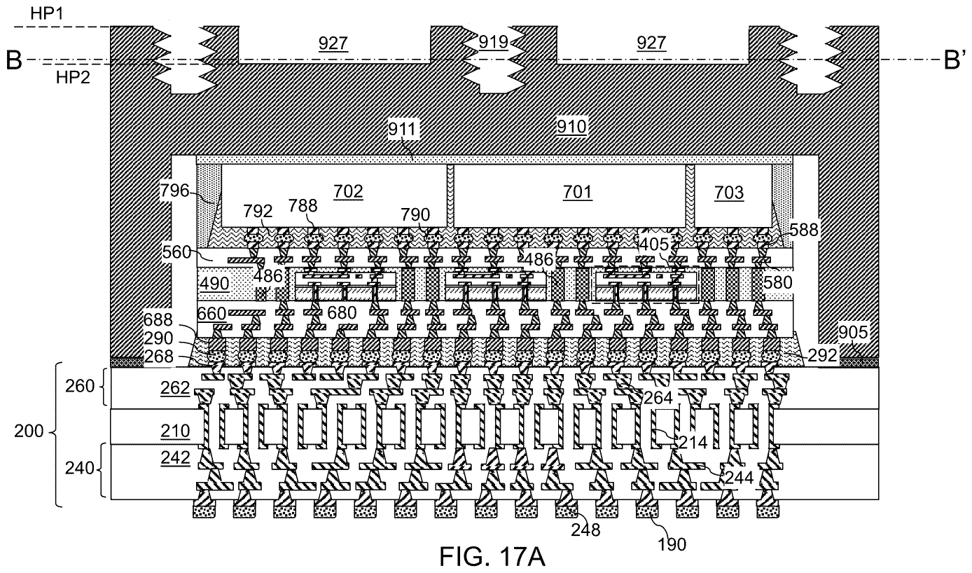

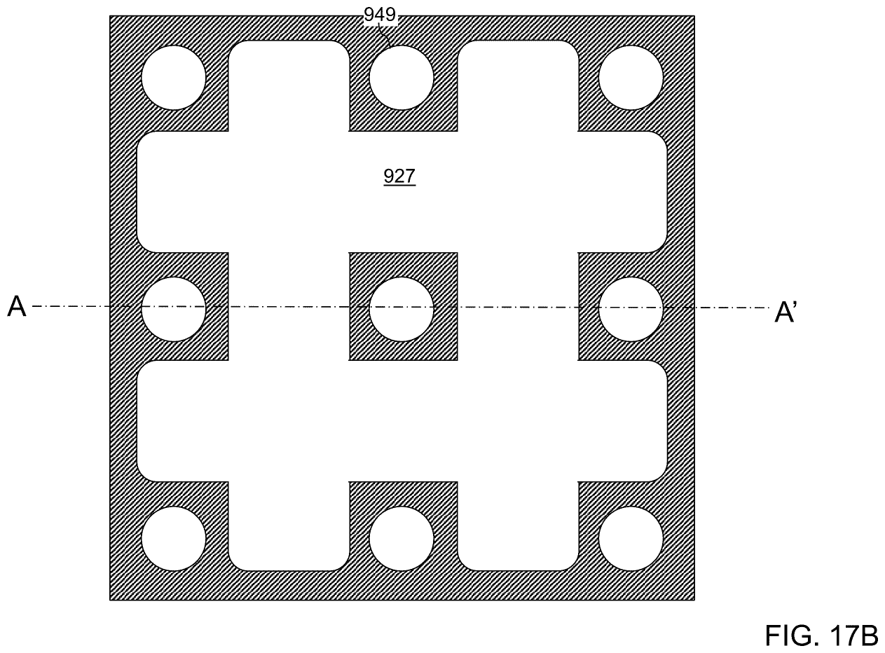

Referring to FIGS. 17A and 17B, a second exemplary packaging structure is illustrated, which may be formed by attaching a lid structure 910 to the bonded assembly (800, 200) of FIG. 12. The lid structure 910 comprises at least one threaded hole 919 vertically extending from a top surface of the lid structure 910 toward the bonded assembly (800, 200). The lid structure 910 may be attached to bonded assembly (800, 200) using methods described above, e.g., using an adhesive layer 905 that is applied between the packaging substrate 200 and a frame-shaped bottom surface of the lid structure 910. In this embodiment, a first thermal interface material (TIM) layer 911 may be applied to each top surface of the at least one semiconductor die (701, 702, 703), and the lid structure 910 may be attached to the at least one semiconductor die (701, 702, 703) through the first TIM layer 911.

In the second exemplary packaging structure, the top surface of the lid structure 910 comprises a basin 927. The at least one threaded hole 919 vertically extends downward from a first horizontal plane HP1 including a topmost horizontal surface segment of the lid structure 910 below a second horizontal plane HP2 including a bottom surface of the basin 927. Thus, the depth of the basin 927 may be less than the vertical extent of the at least one threaded hole 919. In one embodiment, the depth of the basin 927 may be in a range from 50 microns 1 mm, such as from 100 microns to 300 microns, although lesser or greater depths may also be used.

According to an aspect of the present disclosure, the basin 927 does not overlap with any of the at least one threaded hole 919 in a plan view, i.e., a view along a vertical direction such as top-down view or a horizontal cross-sectional view. In one embodiment, the at least one threaded hole 919 comprises a plurality of threaded holes 919. In the configuration illustrated in FIGS. 17A and 17B, a threaded hole 919 selected from the plurality of threaded holes 919 may be laterally surrounded by the basin 927 in a horizontal cross-sectional view that cuts through the basin 927 (such as the view of FIG. 17B), and additional threaded holes 919 selected from the plurality of threaded holes 919 may be located outside the basin 927 in the horizontal cross-sectional view.

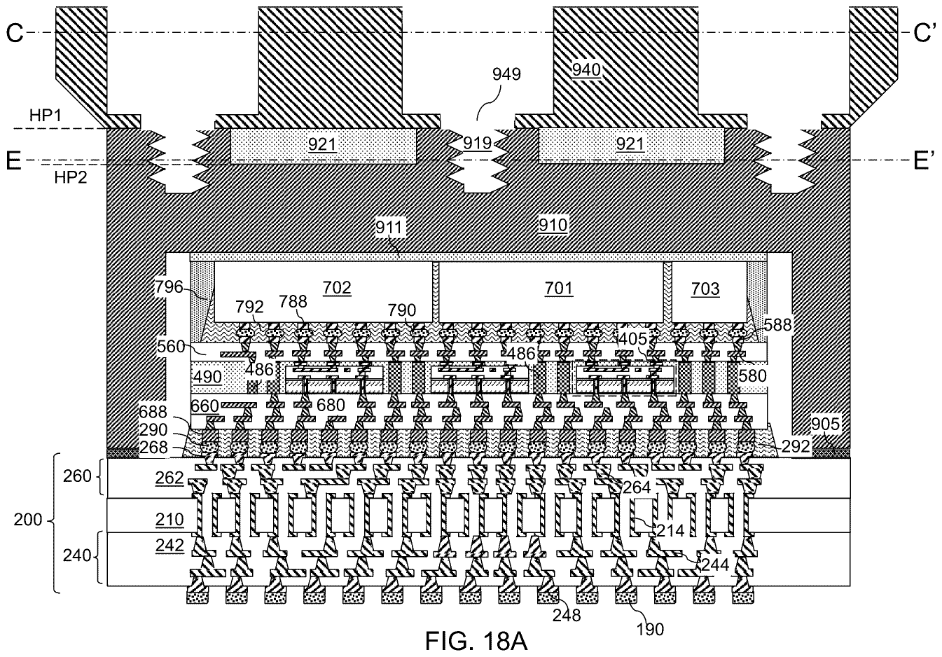

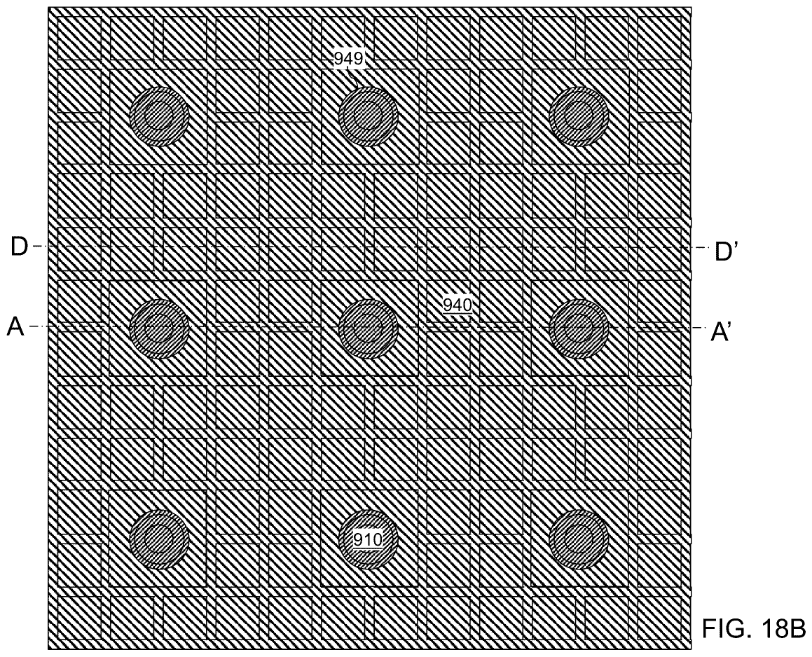

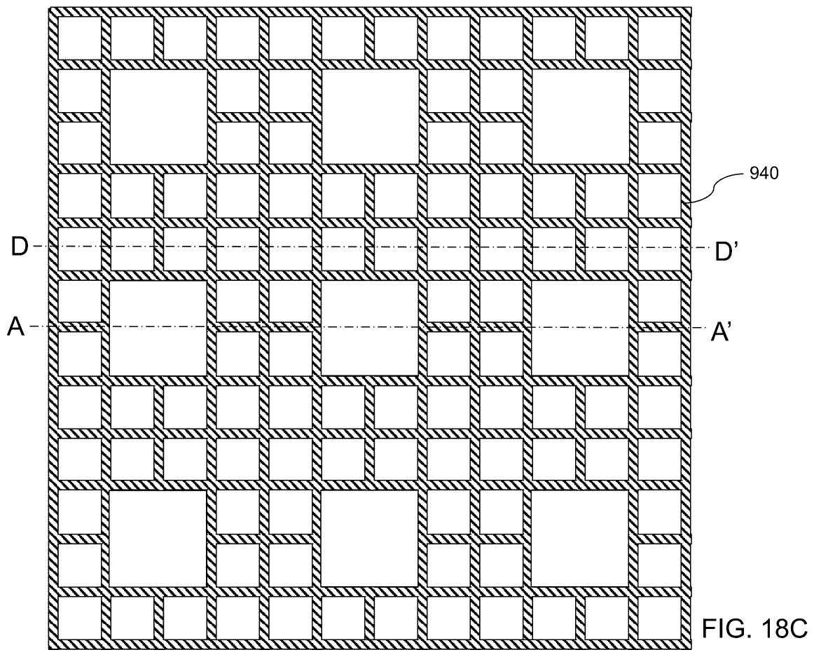

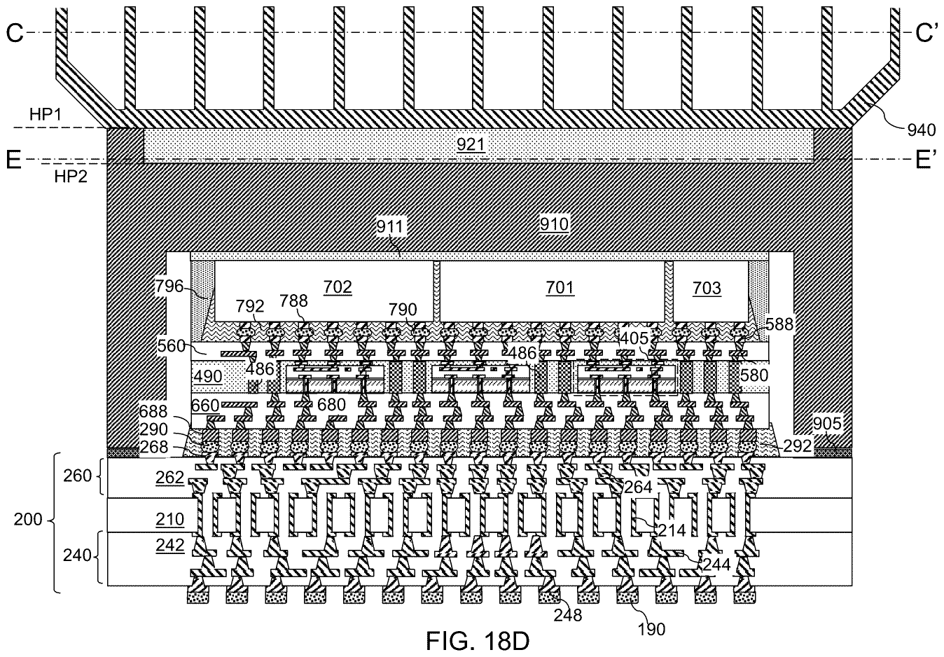

Referring to FIGS. 18A-18E, the basin 927 may be filled with a thermal interface material to form a second thermal interface material (TIM) layer 921. In one embodiment, the amount of the thermal interface material that is applied into the basin 927 may be controlled such that the second TIM layer 921 fills the entire volume of the basin, and the top surface of the second TIM layer 921 is formed at, or about, the first horizontal plane including the topmost horizontal surface segment of the lid structure 910.

A heat sink 940 comprising at least one through-hole 949 may be provided. The heat sink 940 comprises a metallic material providing high electrical conductivity such as copper or aluminum. According to an aspect of the present disclosure, the configuration of the at least one through-hole 949 through the heat sink 940 is selected to match the pattern of the at least one threaded hole 919 in the lid structure 910. If the at least one threaded hole 919 comprises a plurality of threaded holes 919, the at least one through-hole 949 may comprise a plurality of through-holes 949. Generally, the sidewall(s) of the at least one through-hole 949 may be smooth, and the lateral dimensions (such as the diameters) of the at least one through-hole 949 may be selected to allow unobstructed passage of threaded fasteners to be subsequently used.

The heat sink 940 may be attached to the lid structure 910 using the second TIM layer 921. The second TIM layer 921 may comprise any thermal interface material known in the art. The basin area of the lid structure 910 is covered with the second TIM layer 921, while the topmost surface segment of the lid structure 910 and the at least one threaded hole 919 are not covered with the second TIM layer 921. Thus, the heat sink 940 is mounted directly on the lid structure 910 and directly on the TIM layer 921.

The heat sink 940 may comprise a horizontally-extending heat sink plate portion in contact with the second TIM layer 921 and a plurality heat sink fin portions that extend vertically upward from the horizontally-extending heat sink plate portion. In some embodiments, the plurality of heat sink fin portions may be arranged as a grid pattern. According to an embodiment of the present disclosure, the pattern of the plurality of heat sink fin portions is selected to contain an opening over each of the at least one through-hole 949, which extends through the horizontally-extending heat sink plate portion of the heat sink 940. Each opening in the plurality of heat sink fin portions function as a keep-out zone which prevents formation of any physical structure that may hinder application of a threaded fastener in a subsequent processing step.

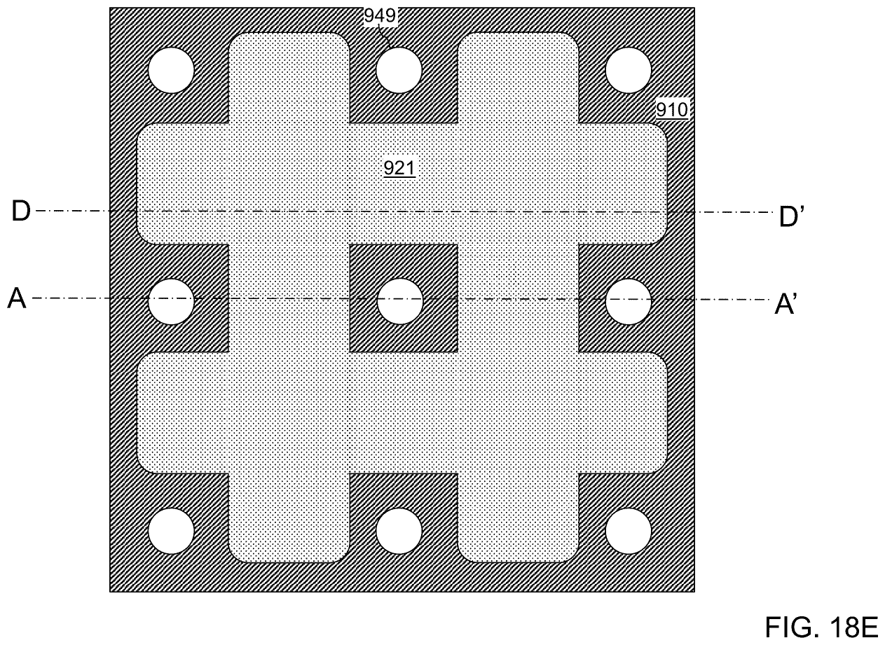

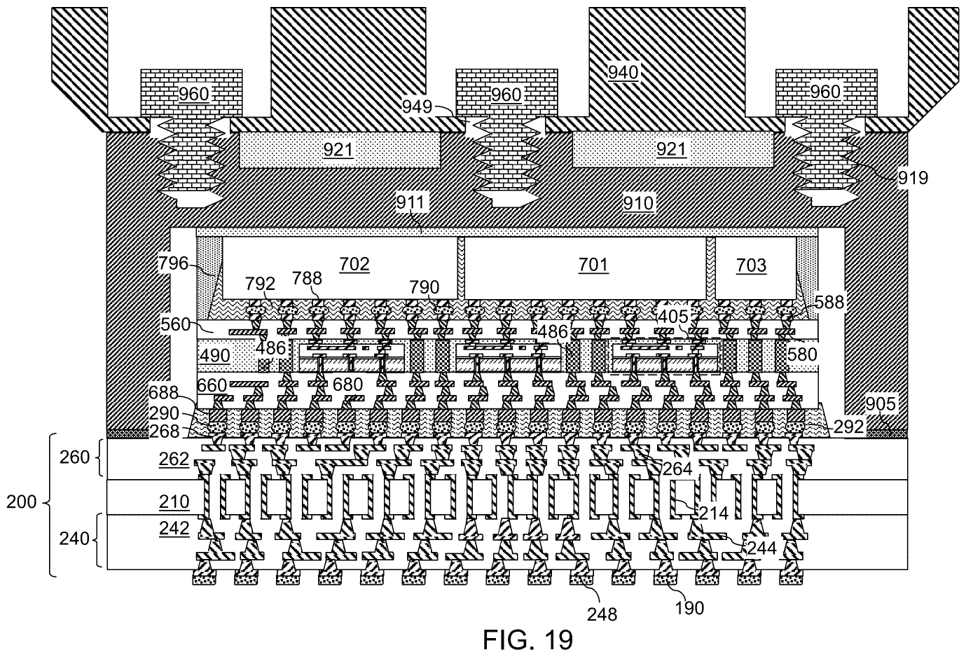

Referring to FIG. 19, the heat sink 940 may be affixed to the lid structure 910 using at least one threaded fastener 960. In other words, the at least one threaded fastener 960 may be used to permanently mount the heat sink 940 to the lid structure 910. The at least one threaded fastener 960 may comprise a plurality of threaded fasteners 960. Each of the at least one threaded fastener 960 may be passed through a respective one of the at least one through-hole 949. Each of the at least one threaded fastener 960 may be engaged into a respective one of the at least one threaded hole 919 so that the heat sink 940 is affixed to the lid structure 910. In embodiment in which the at least one threaded fastener 960 comprises at least one bolt, each of the at least one threaded fastener 960 may fit into a respective threaded hole 919 in the lid structure 910 without changing the shape of the respective threaded hole 919. In embodiment in which the at least one threaded fastener 960 comprises at least one screw, each of the at least one threaded fastener 960 may fit into a respective threaded hole 919 while deforming the respective threaded hole 919.

Generally, the heat sink 940 may be mounted to the lid structure 910 using at least one threaded fastener 960. The at least one threaded fastener 960 is a mechanical structure that provides mechanical attachment between the heat sink 940 and the lid structure 910 irrespective of the deformation that may occur in the lid structure 910 and/or in the heat sink 940 during operation of the packaging structure. Thus, the at least one threaded fastener 960 provides mechanically stable attachment that is not affected by thermal expansion of the lid structure 910, the first TIM layer 911, the second TIM layer 921, and the heat sink 940. The heat sink 940 comprises at least one through-hole 949 through which the at least one threaded fastener 960 passes, and the at least one threaded fastener 960 is threaded into a respective one of the at least one threaded hole 919.

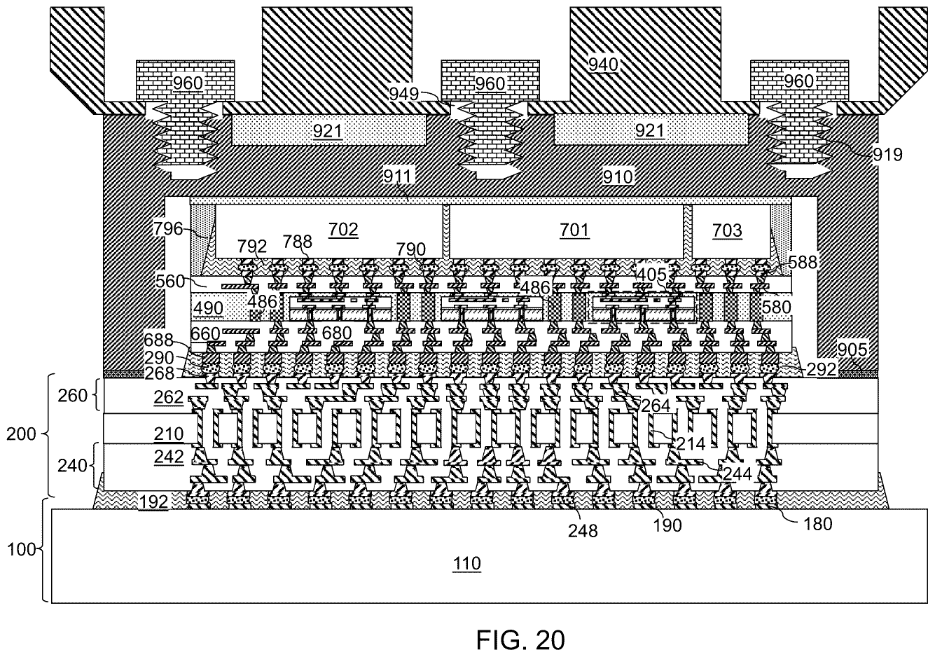

Referring to FIG. 20, a printed circuit board (PCB) 100 including a PCB substrate 110 and PCB bonding pads 180 may be provided. The PCB 100 includes a printed circuitry (not shown) at least on one side of the PCB substrate 110. The printed circuit board 100 may be attached to the bonded assembly of the composite package 800, the packaging substrate 200, the lid structure 910, and the heat sink 940. In one embodiment, the bonded assembly (800, 200) is attached to the printed circuit board 100 using an array of solder material portions 190 that provides solder bonding between the printed circuit board 100 and the packaging substrate 200. In this embodiment, the array of solder material portions 190 may be disposed over the array of PCB bonding pads 180, and may be reflowed to form solder joints that are bonded to a respective pair of a board-side bonding pad 248 and a PCB bonding pad 180. An additional underfill material portion, which is herein referred to as a board-substrate underfill material portion 192 or a BS underfill material portion 192, may be formed around the solder material portions 190 by applying and shaping an underfill material. The packaging substrate 200 is attached to the PCB 100 through the array of solder material portions 190.

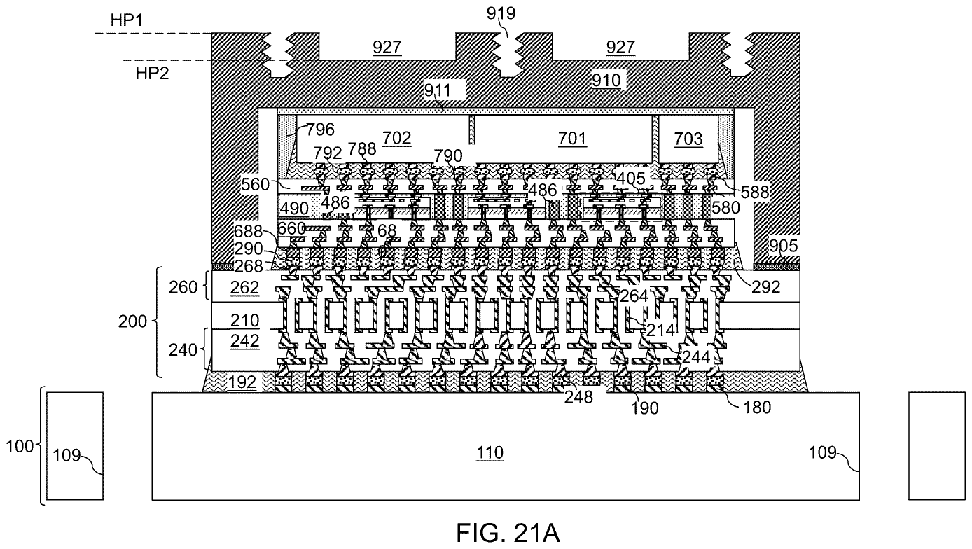

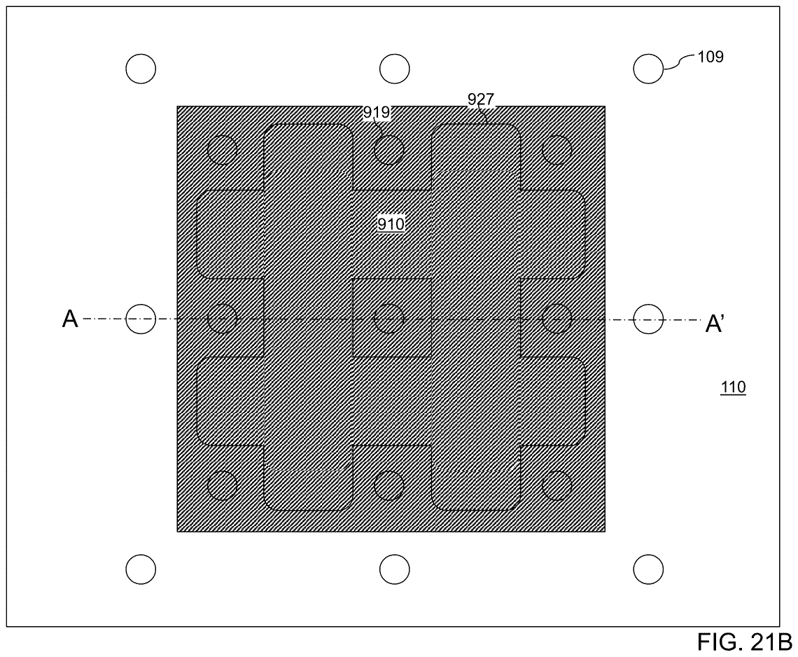

Referring to FIGS. 21A and 21B, a third exemplary packaging structure may be derived from the second exemplary packaging structure of FIGS. 17A and 17B formed by attaching the second exemplary packaging structure of FIGS. 17A and 17B to a printed circuit board 100. Thus, a lid structure 910 may be attached to a bonded assembly (800, 200) including a composite package 800 and a packaging substrate 200, and the bonded assembly (800, 200) may be subsequently attached to the printed circuit board 100. Generally, the processing steps described with reference to FIG. 16 may be used to attach the bonded assembly (800, 200) to the printed circuit board 100. In one embodiment, the bonded assembly (800, 200) is attached to the printed circuit board 100 using an array of solder material portions 190 that provides solder bonding between the printed circuit board 100 and the packaging substrate 200.

According to an aspect of the present disclosure, the printed circuit board 100 comprises at least one through hole, which is herein referred to as at least one through-board hole 109. The at least one through-board hole 109 is positioned in an area in which a wall portion of a heat sink to be subsequently used contacts the printed circuit board 100.

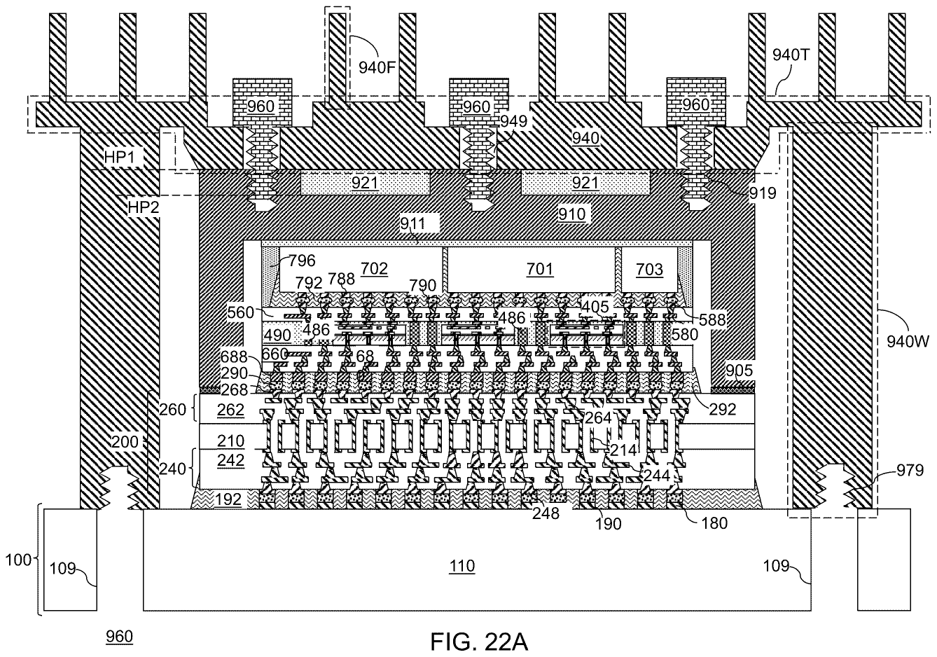

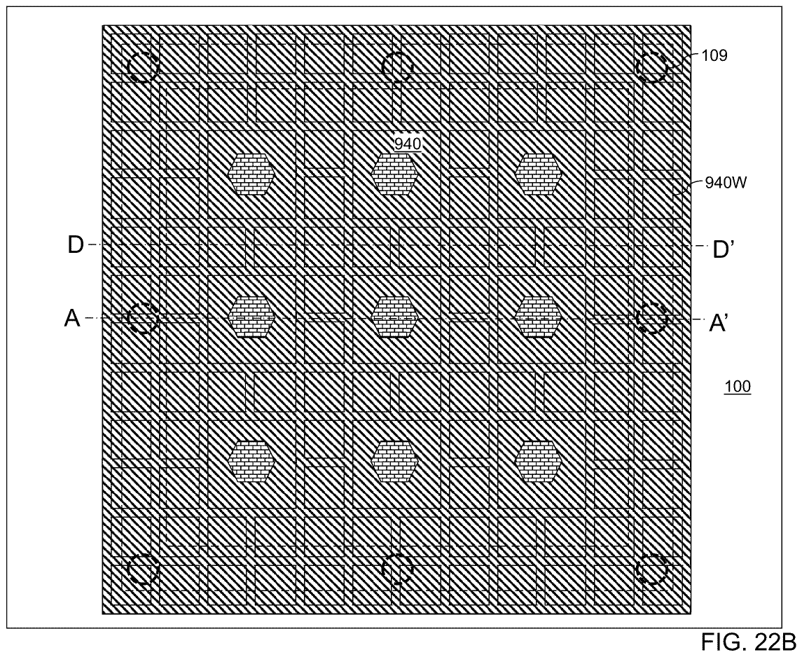

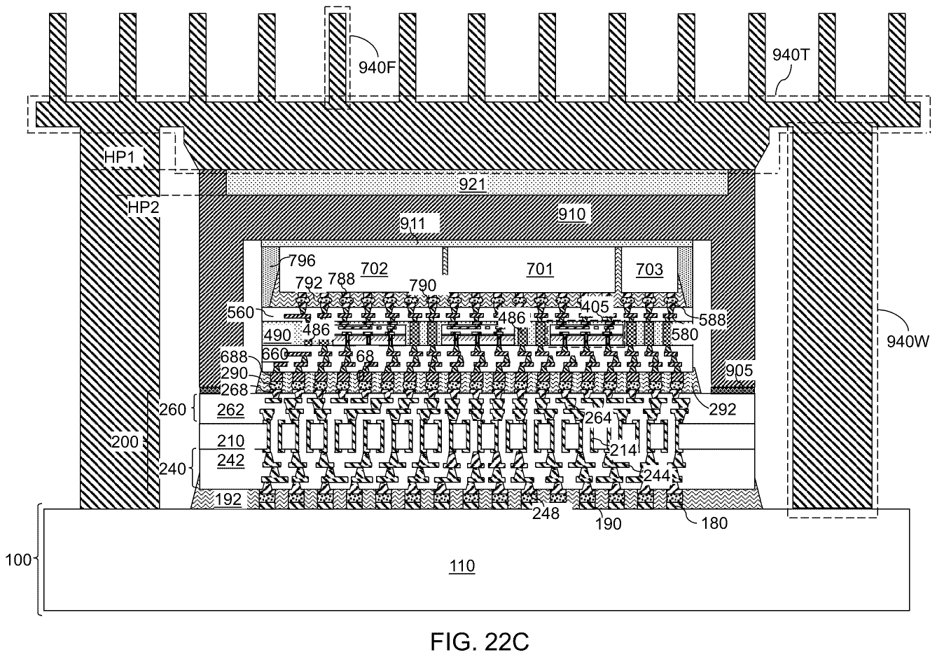

Referring to FIGS. 22A-22C, a heat sink 940 may be provided. The heat sink 940 comprises a heat sink plate portion 940T having a configuration of a perforated plate, containing at least one through-hole 949, and having a lateral extent that is greater than a lateral extent of the bonded assembly (800, 200); a plurality of heat sink fin portions 940F vertically extending upward from a top surface of the heat sink plate portion 940T; and a wall portion 940W vertically extending downward from a peripheral of a bottom surface of the heat sink plate portion 940T. The wall portion 940W may laterally enclose a cavity therein. In one embodiment, the wall portion 940W may have a configuration of a moat. In one embodiment, the wall portion 940W may comprise an assembly of four planar wall structures that are adjoined to one another to provide a vertically-extending structure having a horizontal cross-sectional shape of a rectangular frame, i.e., a frame having an outer rectangular periphery and having an inner rectangular periphery.

The basin 927 may be filled with a thermal interface material to form a second thermal interface material (TIM) layer 921. In one embodiment, the amount of the thermal interface material that is applied into the basin 927 may be controlled such that the second TIM layer 921 fills the entire volume of the basin, and the top surface of the second TIM layer 921 is formed at, or about, the first horizontal plane including the topmost horizontal surface segment of the lid structure 910.

The heat sink 940 may be attached to the lid structure 910 using the second TIM layer 921. The second TIM layer 921 may comprise any thermal interface material known in the art. The basin area of the lid structure 910 is covered with the second TIM layer 921, while the topmost surface segment of the lid structure 910 and the at least one threaded hole 919 are not covered with the second TIM layer 921. Thus, the heat sink 940 is mounted directly on the lid structure 910 and directly on the TIM layer 921.

The heat sink plate portion 940T is in contact with the second TIM layer 921. The heat sink fin portions 940F extend vertically upward from the heat sink plate portion 940T. In some embodiments, the heat sink fin portions 940F may be arranged as a grid pattern. According to an embodiment of the present disclosure, the pattern of the heat sink fin portions 940F is selected to contain an opening over each of the at least one through-hole 949, which extends through the heat sink plate portion 940T of the heat sink 940. Each opening in the heat sink fin portions 940F function as a keep-out zone which prevents formation of any physical structure that may hinder application of a threaded fastener in a subsequent processing step.

The heat sink 940 may be affixed to the lid structure 910 using at least one threaded fastener 960. In other words, the at least one threaded fastener 960 may be used to permanently mount the heat sink 940 to the lid structure 910. The at least one threaded fastener 960 may comprise a plurality of threaded fasteners 960. Each of the at least one threaded fastener 960 may be passed through a respective one of the at least one through-hole 949. Each of the at least one threaded fastener 960 may be engaged into a respective one of the at least one threaded hole 919 so that the heat sink 940 is affixed to the lid structure 910. In embodiment in which the at least one threaded fastener 960 comprises at least one bolt, each of the at least one threaded fastener 960 may fit into a respective threaded hole 919 in the lid structure 910 without changing the shape of the respective threaded hole 919. In embodiment in which the at least one threaded fastener 960 comprises at least one screw, each of the at least one threaded fastener 960 may fit into a respective threaded hole 919 while deforming the respective threaded hole 919.

Generally, the heat sink 940 may be mounted to the lid structure 910 using at least one threaded fastener 960. The at least one threaded fastener 960 is a mechanical structure that provides mechanical attachment between the heat sink 940 and the lid structure 910 irrespective of the deformation that may occur in the lid structure 910 and/or in the heat sink 940 during operation of the packaging structure. Thus, the at least one threaded fastener 960 provides mechanically stable attachment that is not affected by thermal expansion of the lid structure 910, the first TIM layer 911, the second TIM layer 921, and the heat sink 940.

Generally, the heat sink 940 may be mounted to the lid structure 910 using at least one threaded fastener 960. The heat sink 940 comprises at least one through-hole 949 through which the at least one threaded fastener 960 passes, and the at least one threaded fastener 960 is threaded into a respective one of the at least one threaded hole 919. Upon full engagement into the at least one threaded hole 919, i.e., upon affixing the heat sink 940 to the lid structure 910, the at least one threaded fastener 960 is positioned entirely below the horizontal plane including topmost surfaces of the plurality of heat sink fin portions 940F.

According to an aspect of the present disclosure, the heat sink 940 comprises a wall portion 940W that laterally surrounds the bonded assembly (800, 200) upon affixing of the heat sink 940 to the lid structure 910. The wall portion 940W may have a frame-shaped horizontal cross-sectional shape. A frame-shaped bottom surface of the wall portion 940W may be at, or slightly above, the horizontal plane including the top surface of the printed circuit board 100. The frame-shaped bottom surface of the wall portion 940W of the heat sink 940 may comprise at least one additional threaded hole 979, which is herein referred to as at least one heat-sink-side threaded hole 979. In one embodiment, each of at least one heat-sink-side threaded hole 979 may be positioned over a respective through-board hole 109 to provide subsequent mechanical affixing of the wall portion 940W of the heat sink 940 to the printed circuit board 100.

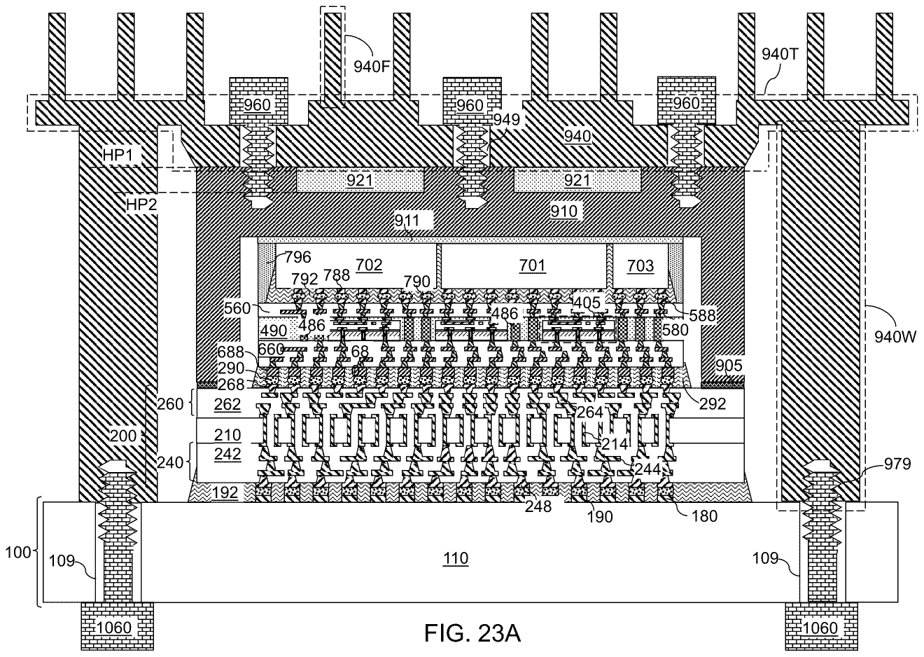

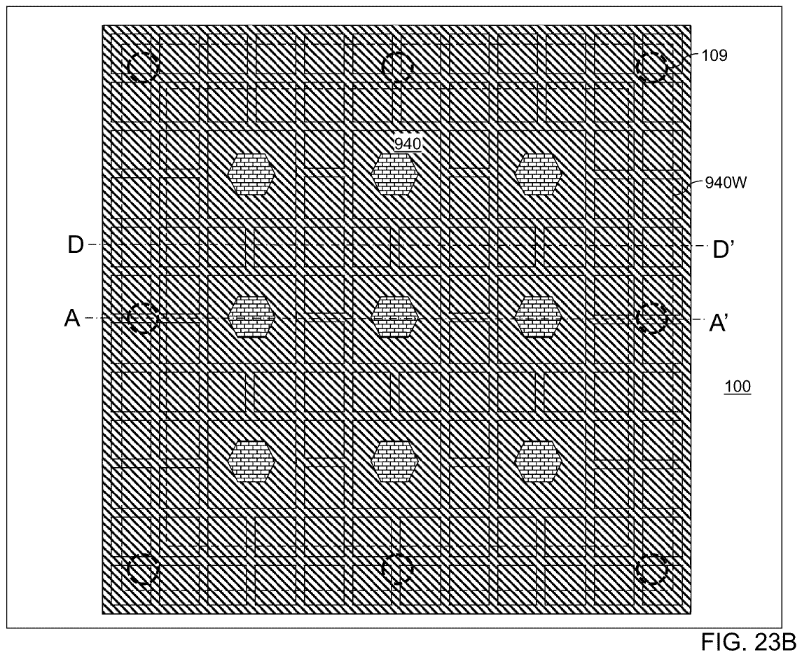

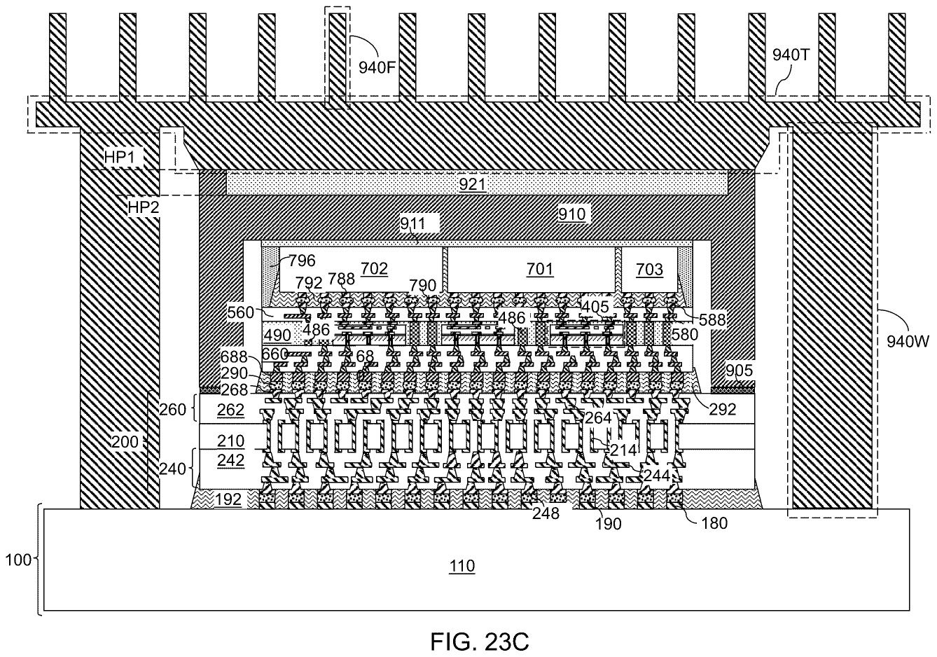

Referring to FIGS. 23A-23C, the bottom end of the wall portion 940W may be affixed to the printed circuit board 100 using at least one additional threaded fastener 1060 that passes through at least one through-board hole 109 in the printed circuit board 100 and engages at least one additional threaded hole 979, i.e., the at least one heat-sink-side threaded hole 979, in the bottom end of the wall portion 940W. The at least one additional threaded fastener 1060 is also referred to as at least one through-board threaded fastener 1060. The at least one through-board threaded fastener 1060 may pass through a respective one of the at least one through-board hole 109, and may engage a respective one of the at least one heat-sink-side threaded hole 979. The wall portion 940W of the heat sink 940 is affixed to the printed circuit board 100.

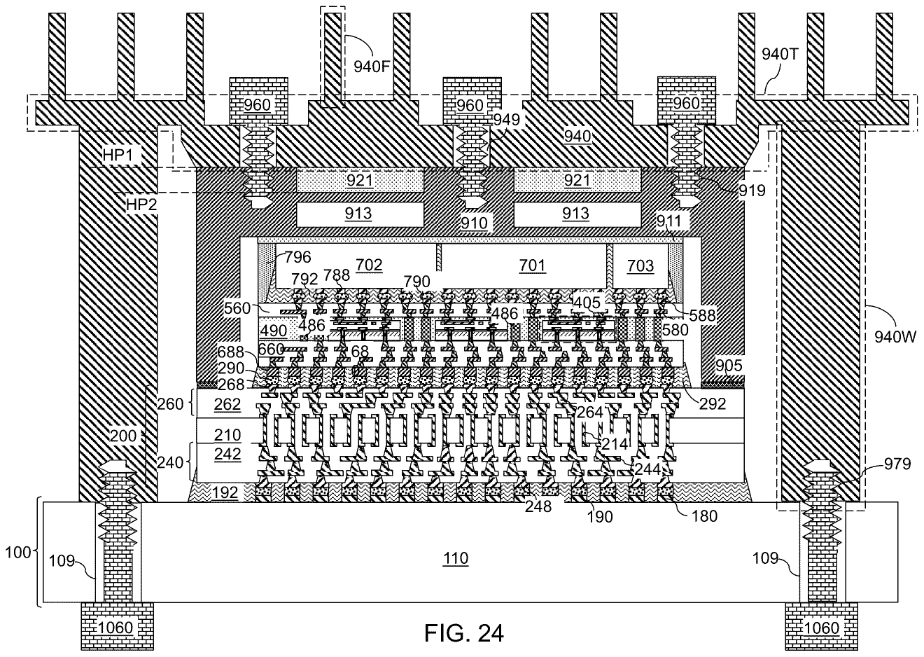

Referring to FIG. 24, an alternative configuration of the third exemplary packaging structure is illustrated after affixing through-board threaded fasteners 960 through the printed circuit board 100 to the heat sink 940 according to an embodiment of the present disclosure. The alternative configuration of the third exemplary packaging structure may be derived from the third exemplary packaging structure illustrated in FIGS. 23A-23C by using a lid structure 910 containing at least one cavity 913 therein. Each cavity 913 may be free of any solid phase material. Each cavity 913 may be filled with an atmospheric gas. The at least one cavity 913 may be advantageously used to affect the heat conduction pattern within the lid structure 910.

According to various embodiments of the present disclosure, a packaging structure may comprise: a bonded assembly (800, 200) comprising at least one semiconductor die (701, 702, 703) and a packaging substrate 200; a lid structure 910 attached to a top surface of the bonded assembly (800, 200) and comprising at least one threaded hole 919 vertically extending from a top surface of the lid structure 910 toward the bonded assembly (800, 200); a heat sink 940 disposed on the lid structure 910 and comprising at least one through-hole 949; and at least one threaded fastener 960 passing through the at least one through-hole 949 and threaded into a respective one of the at least one threaded hole 919.

The packaging structure may further comprise: a printed circuit board 100 that is bonded to the bonded assembly (800, 200) via an array of solder material portions 190; and at least one additional threaded fastener 960 passing through at least one through-board hole 109 in the printed circuit board 100 and engaging at least one heat-sink-side threaded hole 979 in the heat sink 940. In one embodiment, the heat sink 940 comprises: a heat sink plate portion 940T containing the at least one through-hole 949 and having a lateral extent that is greater than a lateral extent of the bonded assembly (800, 200); and a wall portion 940W that laterally surrounds the bonded assembly (800, 200) upon mounting of the heat sink 940 to the lid structure 910, wherein the at least one heat-sink-side threaded hole 979 is provided on a bottom surface of the wall portion 940W.

In one embodiment, the top surface of the lid structure 910 comprises a basin 927; a first thermal interface material (TIM) layer 911 is located between the at least one semiconductor die (701, 702, 703) and a planar bottom surface of the lid structure 910; a second TIM layer 921 is located in the basin 927; and the heat sink 940 contacts a topmost surface segment of the lid structure 910 and a top surface of the second TIM layer 921. In one embodiment, the basin 927 does not overlap with any of the at least one threaded hole 919 in a plan view; and the at least one threaded hole 919 vertically extends downward from a first horizontal plane HP1 including the topmost horizontal surface segment of the lid structure 910 below a second horizontal plane HP2 including a bottom surface of the basin 927.

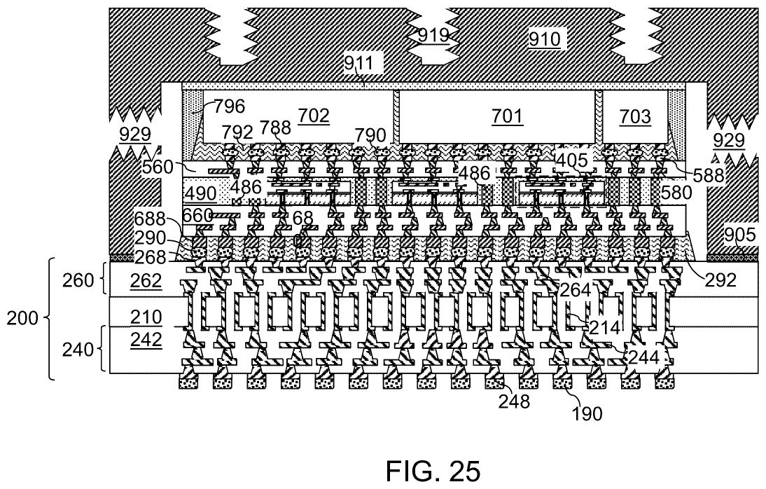

Referring to FIG. 25, a fourth exemplary packaging structure may be derived from any of the first and second packaging structures illustrated in FIGS. 13A and 13B, and 17A and 17B by modifying the lid structure 910. Specifically, the lid structure 910 may be modified to provide at least one threaded side hole 929 containing a respective horizontally-aligned threading.

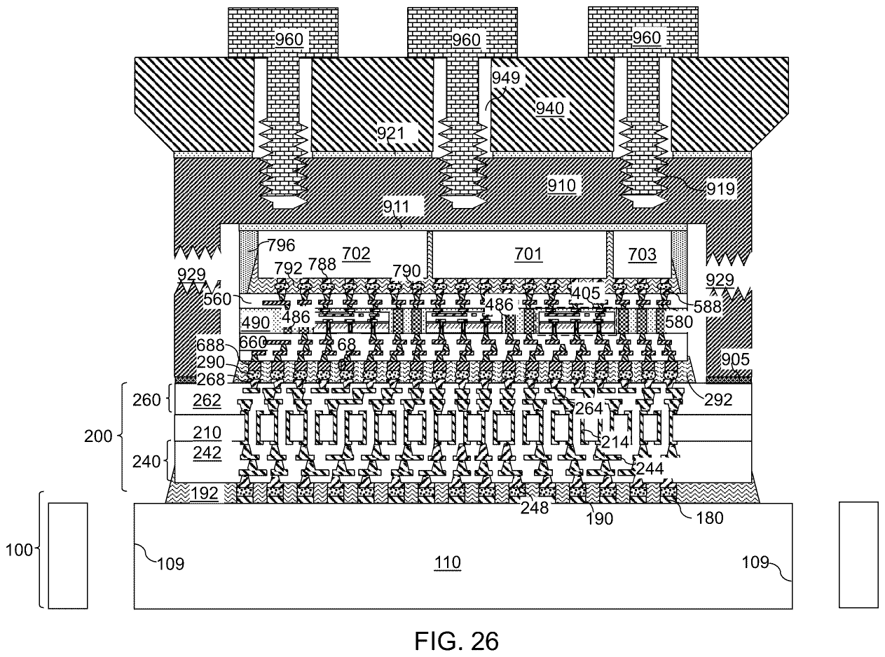

Referring to FIG. 26, a heat sink 940 may be attached to the lid structure 910 and a printed circuit board 100 may be attached to the bonded assembly (800, 200) by performing a suitable set of processing steps described above. For example, the set of processing steps described with reference to FIGS. 14A-15B or the set of processing steps described with reference to FIGS. 18A-19 may be used to attach the heat sink 940 to the lid structure 910. Likewise, the set of processing steps described with reference to FIG. 20 or FIGS. 21A and 21B may be used to attach the printed circuit board 100 to the bonded assembly (800, 200). The attachment of the heat sink 940 to the lid structure 910 may precede, or follow, the attachment of the printed circuit board 100 to the bonded assembly (800, 200).

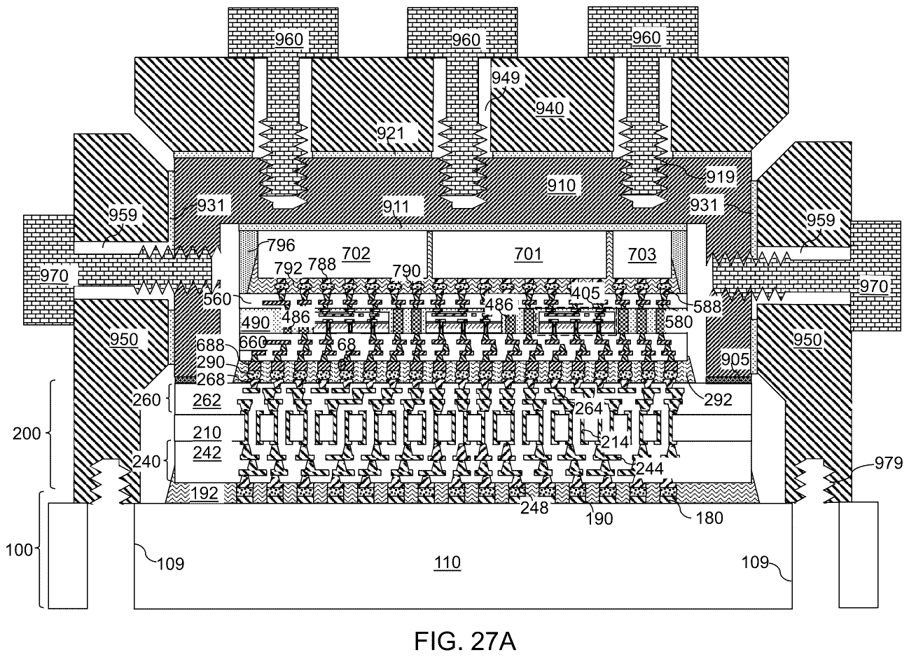

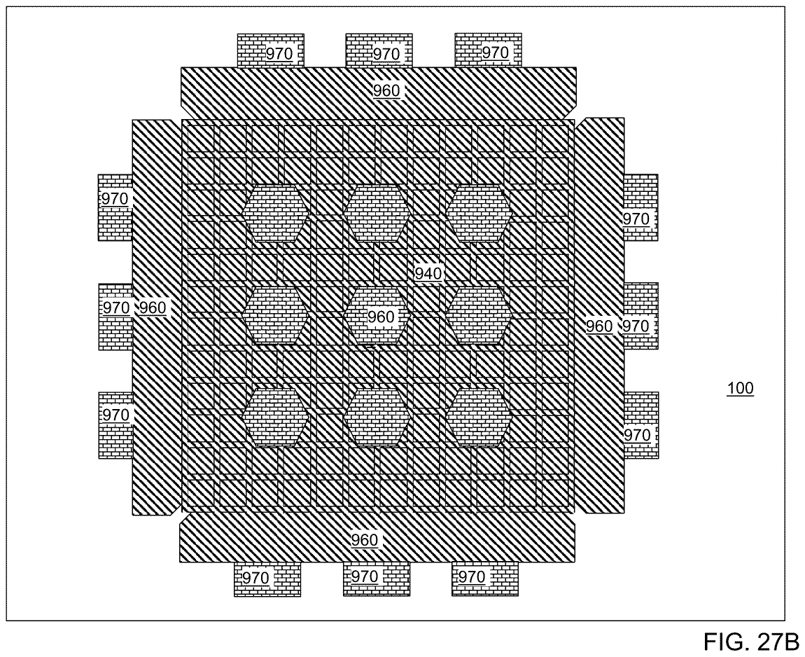

Referring to FIGS. 27A and 27B, side heat sinks 950 may be attached to sidewalls of the lid structure 910 using side thermal interface material layers 931 and side threaded fasteners 970. Each of the side heat sinks 950 may comprise a respective lateral through hole 959 through which a respective side threaded fastener 970 may pass. Each side threaded fastener 970 engages a respective threaded side hole 929 in the lid structure 910. Each side heat sink 950 may comprise a bottom surface containing a respective additional threaded hole 979, which is herein referred to as a heat-sink-side threaded hole 979. In one embodiment, each heat-sink-side threaded hole 979 may be positioned over a respective through-board hole 109 to provide subsequent mechanical affixing of the side heat sinks 950 to the printed circuit board 100. The heat sink 940 and the side heat sinks 950 are discrete components a multi-piece heat sink system that includes at least one threaded fastener 960 and side threaded fasteners 970.

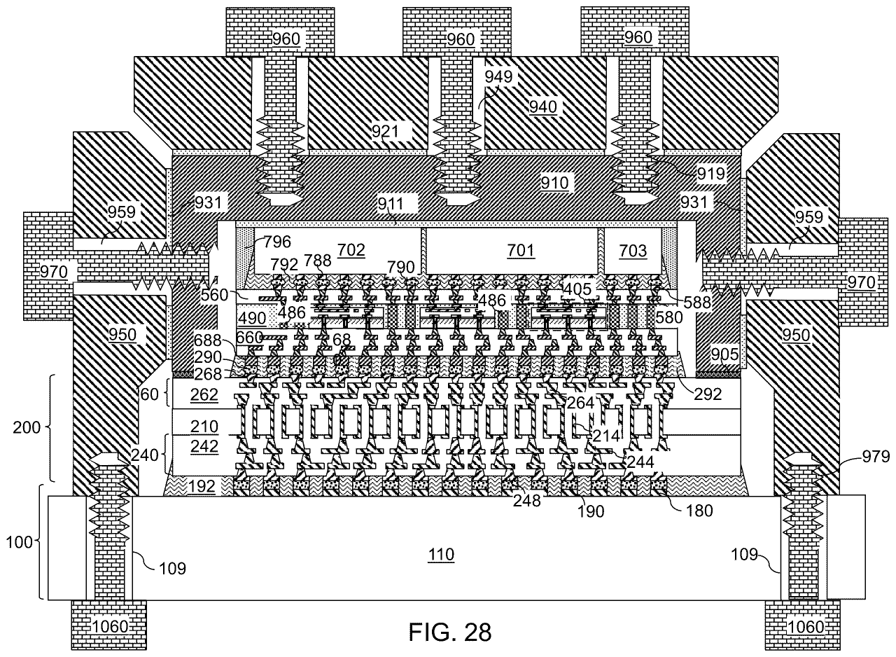

Referring to FIG. 28, each side heat sink 950 may be affixed to the printed circuit board 100 using additional threaded fasteners 1060 that pass through the through-board holes 109 in the printed circuit board 100 and engage the additional threaded holes 979, i.e., the heat-sink-side threaded holes 979, in the bottom end of the side heat sinks 950. The at least one additional threaded fastener 1060 is also referred to as at least one through-board threaded fastener 1060. Each through-board threaded fastener 1060 may pass through a respective through-board hole 109, and may engage a respective heat-sink-side threaded hole 979. The side heat sinks 950 are affixed to the printed circuit board 100.

Across all embodiments of the present disclosure, the pattern of the threaded fasteners 960 may be any pattern provided that the threaded fasteners 960 provide secure attachment of the lid structure 910 to the packaging substrate 200. Further, across all embodiments that use side threaded fasteners 970, the pattern of the side threaded fasteners 970 may have any pattern provided that the side threaded fasteners 970 provide secure attachment of the side heat sinks 950 to the lid structure 910. In addition, across all embodiments that use additional threaded fasteners 1060, the pattern of the additional threaded fasteners 1060 may be any pattern provided that the additional threaded fasteners 1060 provide secure attachment of the wall portion 940W of the heat sink 940 to the printed circuit board 100.

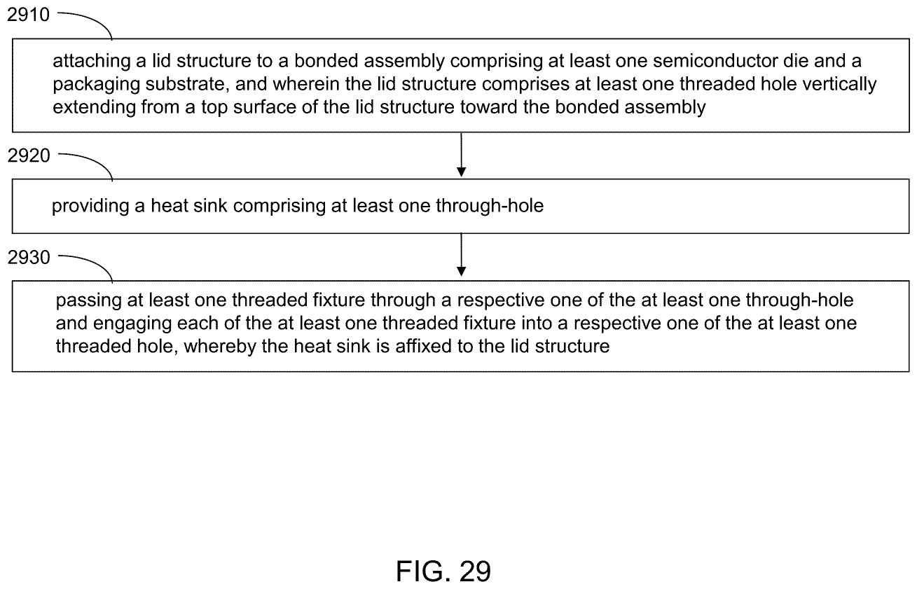

FIG. 29 is a first flowchart illustrating steps for forming a packaging structure according to an embodiment of the present disclosure.

Referring to step 2910 and FIGS. 1-13B, 17A and 17B, and 25, a lid structure 910 may be attached to a bonded assembly (800, 200) comprising at least one semiconductor die (701, 702, 703) and a packaging substrate 200. The lid structure 910 comprises at least one threaded hole 919 vertically extending from a top surface of the lid structure 910 toward the bonded assembly (800, 200).

Referring to step 2920 and FIGS. 14A-14D, 18A-18E, 21A-22C, and 26, a heat sink 940 comprising at least one through-hole 949 may be provided.

Referring to step 2930 and FIGS. 15A-16, 19 and 20, 23A-24, and 26-28, at least one threaded fastener 960 may be passed through a respective one of the at least one through-hole 949, and each of the at least one threaded fastener 960 may be engaged into a respective one of the at least one threaded hole 919. The heat sink 940 is affixed to the lid structure 910.

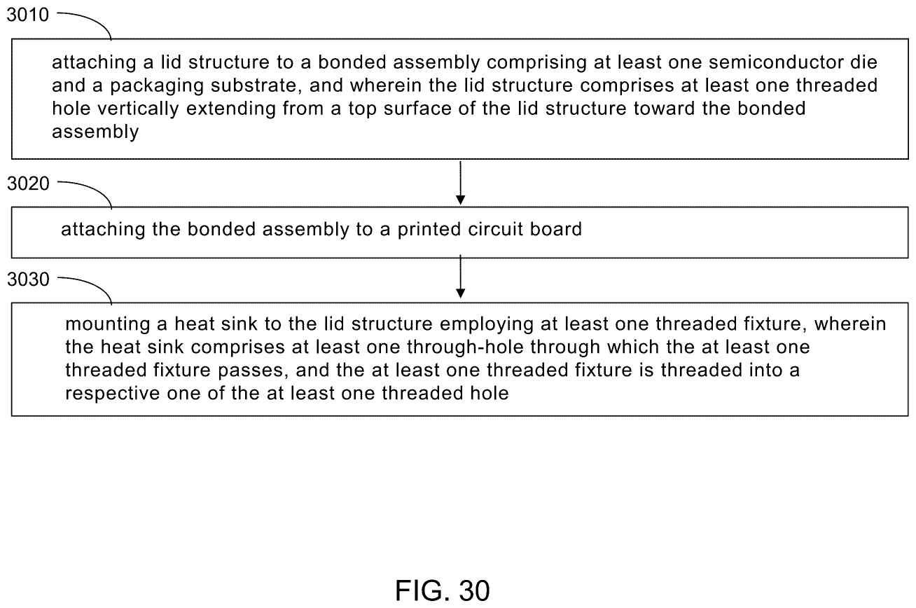

FIG. 30 is a second flowchart illustrating steps for forming a packaging structure according to an embodiment of the present disclosure.

Referring to step 3010 and FIGS. 1-13B, 17A and 17B, and 25, a lid structure 910 may be attached to a bonded assembly (800, 200) comprising at least one semiconductor die (701, 702, 703) and a packaging substrate 200. The lid structure 910 comprises at least one threaded hole 919 vertically extending from a top surface of the lid structure 910 toward the bonded assembly (800, 200).

Referring to step 3020 and FIGS. 16, 20, 21A and 21B, and 26, the bonded assembly (800, 200) may be attached to a printed circuit board 100.

Referring to step 3030 and FIGS. 14A-15B, 18A-19, 22A-24, and 26-28, a heat sink 940 may be mounted to the lid structure 910 using at least one threaded fastener 960. The heat sink 940 comprises at least one through-hole 949 through which the at least one threaded fastener 960 passes, and the at least one threaded fastener 960 is threaded into a respective one of the at least one threaded hole 919.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a packaging structure, the method comprising:
attaching a lid structure to a bonded assembly comprising at least one semiconductor die and a packaging substrate, and wherein the lid structure comprises at least one threaded hole vertically extending from a top surface of the lid structure toward the bonded assembly;
providing a heat sink comprising at least one through-hole; and
passing at least one threaded fastener through a respective one of the at least one through-hole and engaging each of the at least one threaded fastener into a respective one of the at least one threaded hole, whereby the heat sink is affixed to the lid structure.

2. The method of claim 1, further comprising bonding the bonded assembly to a printed circuit board.

3. The method of claim 2, wherein:
the heat sink comprises a wall portion that laterally surrounds the bonded assembly upon affixing of the heat sink to the lid structure; and
the method comprises affixing a bottom end of the wall portion to the printed circuit board.

4. The method of claim 3, wherein the bottom end of the wall portion is affixed to the printed circuit board using at least one additional threaded fastener that passes through at least one through-board hole in the printed circuit board and engages at least one additional threaded hole in the bottom end of the wall portion.

5. The method of claim 1, further comprising applying a first thermal interface material (TIM) layer to each top surface of the at least one semiconductor die, wherein the lid structure is attached to the at least one semiconductor die through the first TIM layer.

6. The method of claim 5, wherein:
the top surface of the lid structure comprises a basin;
the method comprises filling the basin with a second TIM layer; and
the heat sink is disposed directly on the lid structure and directly on the second TIM layer.

7. The method of claim 6, wherein:
the basin does not overlap with any of the at least one threaded hole in a plan view; and
the at least one threaded hole vertically extends downward from a first horizontal plane including a topmost horizontal surface segment of the lid structure below a second horizontal plane including a bottom surface of the basin.

8. The method of claim 6, wherein:
the at least one threaded hole comprises a plurality of threaded holes;
a threaded hole selected from the plurality of threaded holes is laterally surrounded by the basin in a horizontal cross-sectional view that cuts through the basin; and
additional threaded holes selected from the plurality of threaded holes is located outside the basin in the horizontal cross-sectional view.

9. The method of claim 1, wherein the heat sink comprises:
a heat sink plate portion containing the at least one through-hole and having a lateral extent that is greater than a lateral extent of the bonded assembly; and
a plurality of heat sink fin portions vertically extending upward from a top surface of the heat sink plate portion,
wherein the at least one threaded fastener is positioned below a horizontal plane including topmost surfaces of the plurality of heat sink fin portions upon affixing the heat sink to the lid structure.

10. The method of claim 1, wherein the lid structure is attached to the bonded assembly using an adhesive layer that bonds the lid structure to the packaging substrate.

11. A method of forming a packaging structure, the method comprising:
attaching a lid structure to a bonded assembly comprising at least one semiconductor die and a packaging substrate, and wherein the lid structure comprises at least one threaded hole vertically extending from a top surface of the lid structure toward the bonded assembly;
attaching the bonded assembly to a printed circuit board; and
mounting a heat sink to the lid structure using at least one threaded fastener, wherein the heat sink comprises at least one through-hole through which the at least one threaded fastener passes, and the at least one threaded fastener is threaded into a respective one of the at least one threaded hole.

12. The method of claim 11, wherein:
the printed circuit board comprises at least one through-board hole therethrough;
a bottom portion of the heat sink comprises at least one heat-sink-side threaded hole; and
the method comprises passing at least one additional threaded fastener through the at least one through-board hole and engaging the at least one additional threaded fastener into the at least one heat-sink-side threaded hole, whereby the heat sink is mounted on the printed circuit board.

13. The method of claim 12, wherein:
the heat sink comprises a wall portion that laterally surrounds the bonded assembly upon mounting of the heat sink to the lid structure;
the at least one heat-sink-side threaded hole is provided on a bottom surface of the wall portion; and
the bottom surface of the wall portion contacts a top surface of the printed circuit board upon mounting the heat sink on the printed circuit board.

14. The method of claim 11, wherein:
the top surface of the lid structure comprises a basin;
the method comprises filling the basin with a thermal interface material (TIM) layer; and
the heat sink is mounted directly on the lid structure and directly on the TIM layer.

15. The method of claim 11, wherein the bonded assembly is attached to the printed circuit board using an array of solder material portions that provides solder bonding between the printed circuit board and the packaging substrate.

16. A packaging structure comprising:
a bonded assembly comprising at least one semiconductor die and a packaging substrate;
a lid structure attached to a top surface of the bonded assembly and comprising at least one threaded hole vertically extending from a top surface of the lid structure toward the bonded assembly;
a heat sink disposed on the lid structure and comprising at least one through-hole; and
at least one threaded fastener passing through the at least one through-hole and threaded into a respective one of the at least one threaded hole.

17. The packaging structure of claim 16, further comprising:
a printed circuit board that is bonded to the bonded assembly via an array of solder material portions; and
at least one additional threaded fastener passing through at least one through-board hole in the printed circuit board and engaging at least one heat-sink-side threaded hole in the heat sink.

18. The packaging structure of claim 17, wherein the heat sink comprises:
a heat sink plate portion containing the at least one through-hole and having a lateral extent that is greater than a lateral extent of the bonded assembly; and
a wall portion that laterally surrounds the bonded assembly upon mounting of the heat sink to the lid structure, wherein the at least one heat-sink-side threaded hole is provided on a bottom surface of the wall portion.

19. The packaging structure of claim 16, wherein:
the top surface of the lid structure comprises a basin;
a first thermal interface material (TIM) layer is located between the at least one semiconductor die and a planar bottom surface of the lid structure;
a second TIM layer is located in the basin; and
the heat sink contacts a topmost surface segment of the lid structure and a top surface of the second TIM layer.

20. The packaging structure of claim 19, wherein:
the basin does not overlap with any of the at least one threaded hole in a plan view; and
the at least one threaded hole vertically extends downward from a first horizontal plane including the topmost horizontal surface segment of the lid structure below a second horizontal plane including a bottom surface of the basin.
